(19) United States
(12) Patent Application Publication
(10) Pub. No.: US 2026/0053062 A1
(43) Pub. Date: Feb. 19, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Yi-Chen Li, Taichung City (TW); Jen-Yuan Chang, Hsinchu City (TW)

(73) Assignee: Taiwan Semiconductor Manufacturing Company, Ltd., Hsinchu (TW)

(21) Appl. No.: 18/808,048

(22) Filed: Aug. 18, 2024

(51) Int. Cl. H01L 25/065; H01L 23/31; H01L 23/528

(52) U.S. Cl. CPC H01L 25/0652; H01L 23/3114; H01L 23/5283; H01L 2225/06541

(57) ABSTRACT

A semiconductor device includes a die stack. The die stack includes a first tier including a first die and a second tier disposed over the first tier and including a second die and a plurality of through vias, where the plurality of through vias penetrate through the second die and further extend into a part of the first tier to be electrically coupled to the first die.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 11 are schematic cross-sectional views of various stages in manufacturing a semiconductor device in accordance with some embodiments of the disclosure.

FIG. 12 through FIG. 15 are schematic, cross-sectional and enlarged views respectively showing various embodiments of contacting configuration of a through via and a bonding pad in a semiconductor device in accordance with some embodiments of the disclosure.

FIG. 16 through FIG. 18 are schematic, cross-sectional views respectively showing various embodiments of a semiconductor device in accordance with some embodiments of the disclosure.

FIG. 19 is a schematic, cross-sectional views showing a semiconductor device in accordance with alternative embodiments of the disclosure.

FIG. 20 is a schematic cross-sectional view showing an application of a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

As used herein, “around,” “about,” “approximately,” or “substantially” shall generally mean within 20 percent, or within 10 percent, or within 5 percent, or within 3 percent, or within 1 percent of a given value or range. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some embodiments, the method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor device and a manufacturing method thereof, and is not intended to limit the scope of the disclosure. In some embodiments, the semiconductor device may be or include a part of a system-on-integrated-circuit (SoIC) device, an integrated fan-out (InFO) package, a chip-on wafer (CoW) package, a system-on-wafer (SoW), a chip-on wafer-on-substrate (CoWoS) package, a package-on-package (PoP), an InFO package with POP, a wafer-level package (WLP), a device or package of three-dimensional fabric (3Dfabric), or the like. The disclosure is not limited thereto. In accordance with some embodiments, the semiconductor device includes a stacking structure having two or more tiers, where each of the tier includes one or more (semiconductor) dies or chips, and the tiers are electrically coupled to each other through a through via(s) penetrating one tier toward another respective tier. In accordance with some embodiments, the through via(s) is formed to establish proper electrical connections between the (semiconductor) dies or chips of different tiers after the bonding process of the different tiers included in the stacking structure of the semiconductor device, thereby reducing the issue involving metal non-bond defects during conventional bonding processes. Therefore, with the through via(s) in the disclosure, the manufacture yield is improved and the manufacturing cost is also reduced. In addition, with such through via(s), different nodes of (semiconductor) dies or chips are allowed to be integrated into the same tier and later-electrically connected to the (semiconductor) dies or chips included in above or underneath tier thereof. In accordance with some embodiments, due to the formation of the through via(s), the material of bonding pads to be electrically coupled to the through via(s) may be the same or different, which increases the process window of the manufacturing process of the semiconductor device.

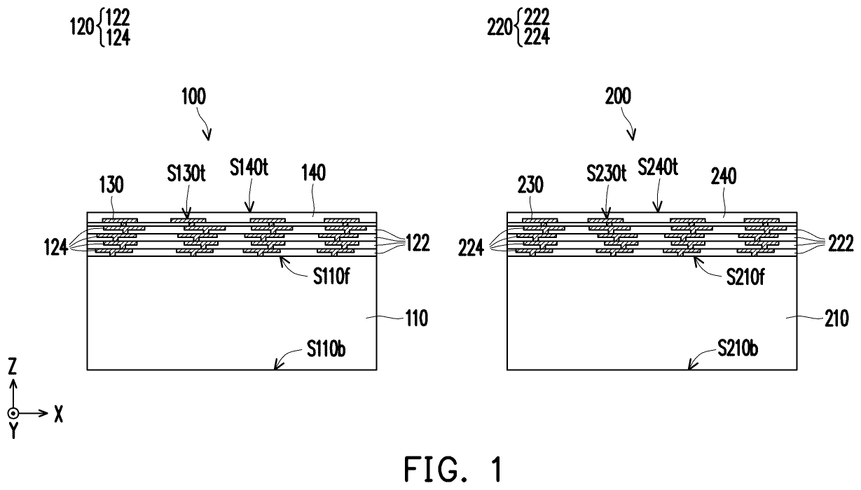

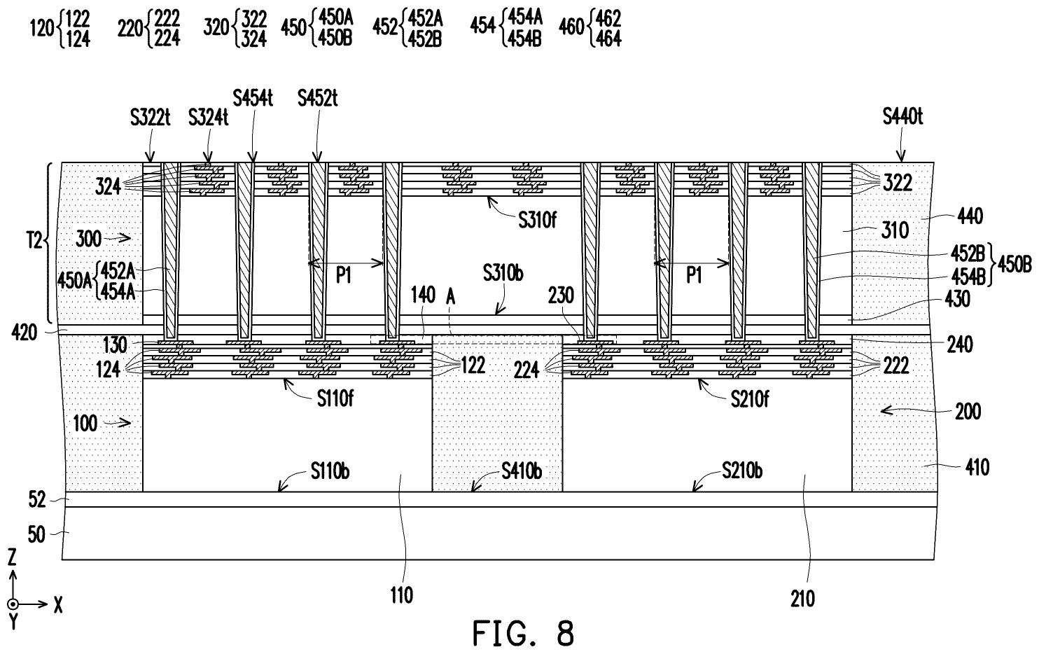

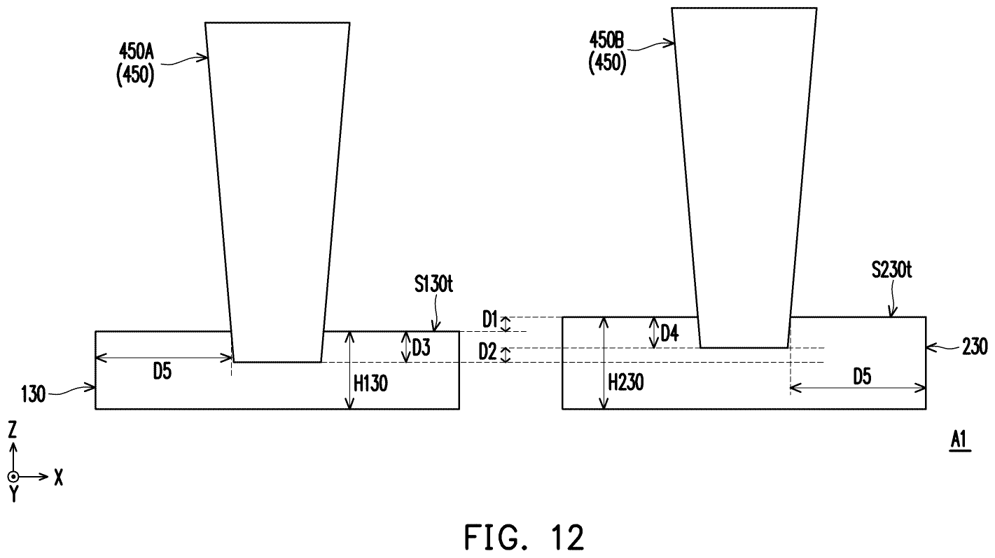

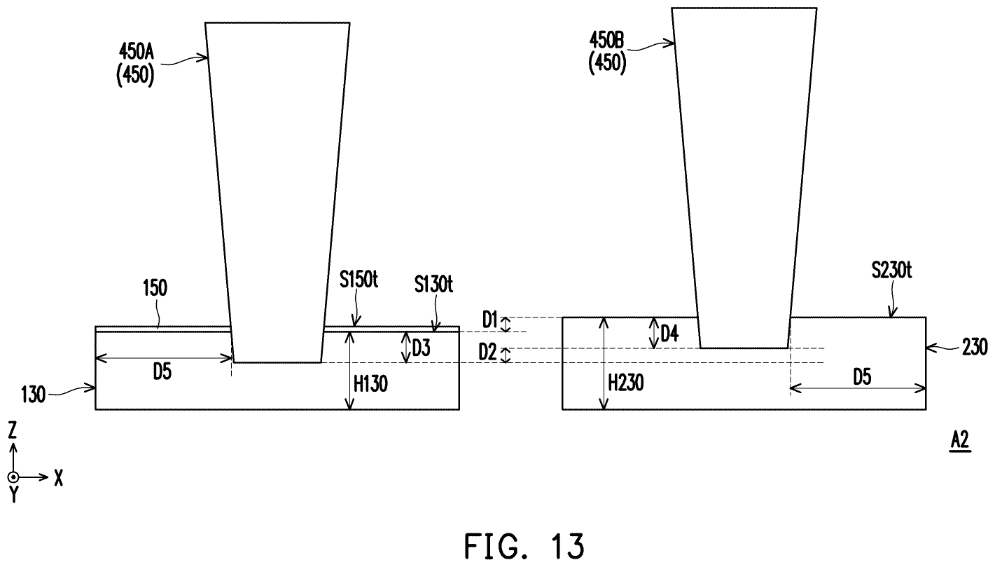

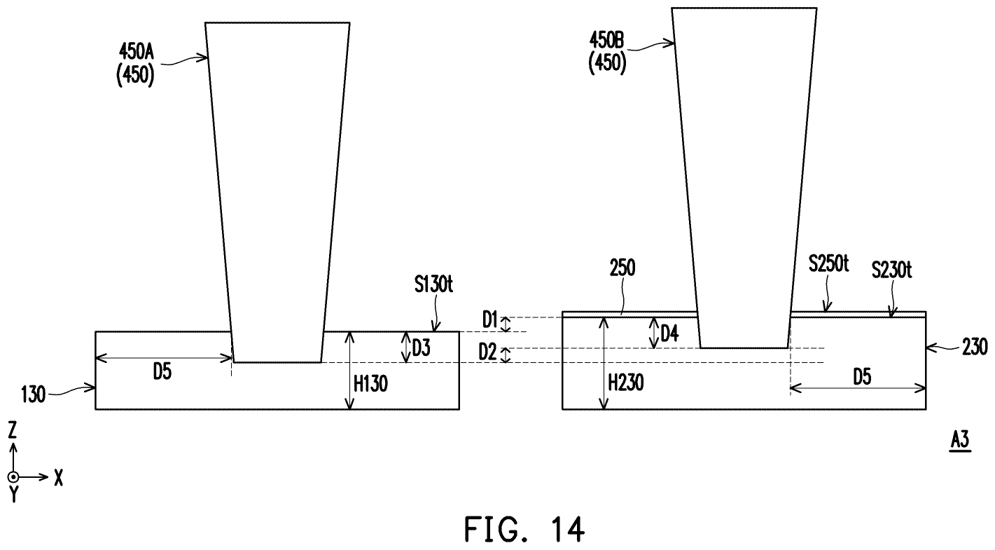

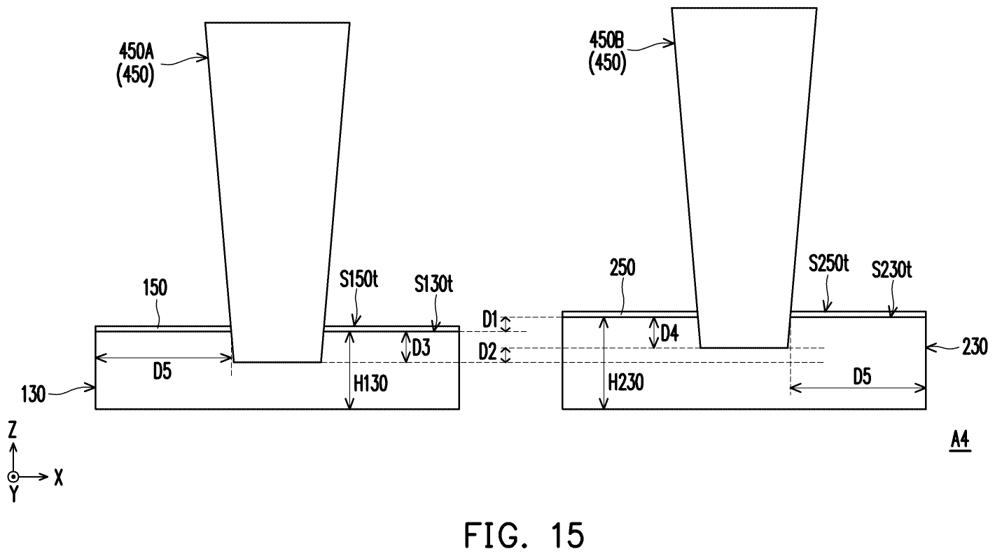

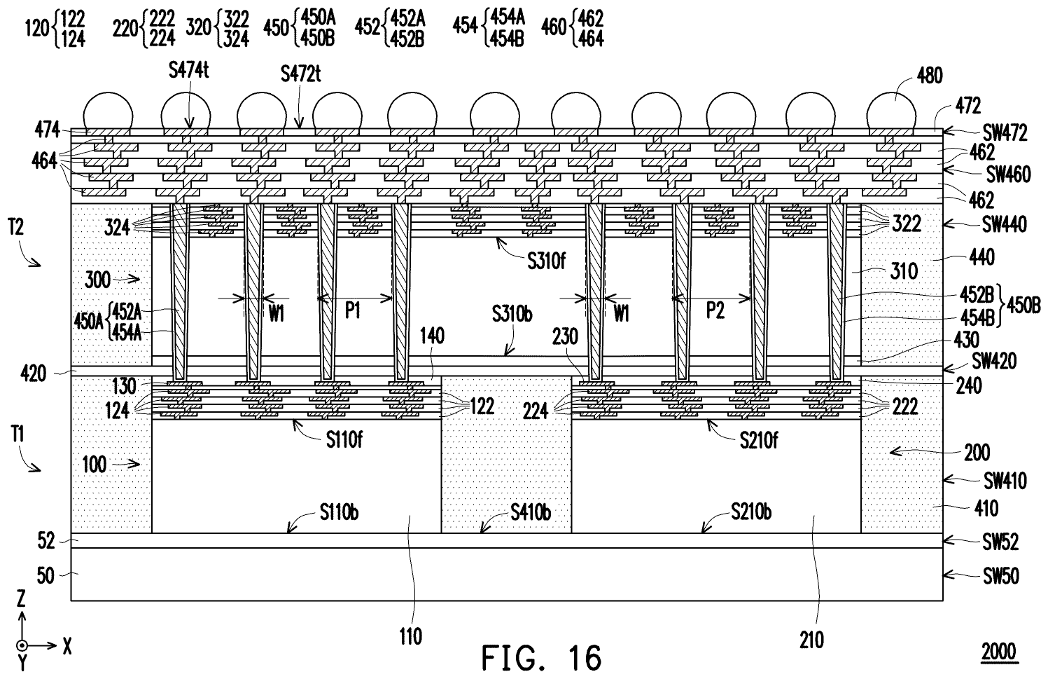

FIG. 1 through FIG. 11 are schematic cross-sectional views of various stages in manufacturing a semiconductor device (e.g., 1000) in accordance with some embodiments of the disclosure. FIG. 12 through FIG. 15 are schematic, cross-sectional and enlarged views respectively showing various embodiments of contacting configuration of a through via and a bonding pad in the semiconductor device of FIG. 8, which are outlined by a dashed-box A depicted in FIG. 8 (e.g., a dashed-box A1 in FIG. 12, a dashed-box A2 in FIG. 13, a dashed-box A3 in FIG. 14, and/or a dashed-box A4 in FIG. 15). FIG. 16 through FIG. 18 are schematic, cross-sectional views respectively showing various embodiments of a semiconductor device (e.g., 2000, 3000, or 4000) in accordance with some embodiments of the disclosure. For clarity of illustrations, the drawings are illustrated with orthogonal axes (X, Y and Z) of a Cartesian coordinate system according to which the views are oriented; however, the disclosure is not specifically limited thereto. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated.

Referring to FIG. 1, in some embodiments, at least one semiconductor die is provided. For illustrative purposes and simplicity, the at least one semiconductor die includes only one semiconductor die 100 and one semiconductor die 200 as shown in FIG. 1; however, the disclosure is not limited thereto.

In some embodiments, the semiconductor die 100 includes a semiconductor substrate 110, an interconnect structure 120 disposed on the semiconductor substrate 110, a plurality of conductive pads 130 disposed on and electrically coupled to the interconnect structure 120, and a dielectric layer 140 disposed on and covering the conductive pads 130 and the interconnect structure 120 exposed by the conductive pads 130. As shown in FIG. 1, the semiconductor substrate 110 has a frontside surface S110f and a backside surface S110b opposite to the frontside surface S110f, and the interconnect structure 120 is located on the frontside surface S110f of the semiconductor substrate 110, where the interconnect structure 120 is sandwiched between the semiconductor substrate 110 and the conductive pads 130 and sandwiched between the semiconductor substrate 110 and the dielectric layer 140, for example.

In some embodiments, the semiconductor substrate 110 is a silicon substrate including active components (e.g., transistors and/or memories such as N-type metal-oxide semiconductor (NMOS) and/or P-type metal-oxide semiconductor (PMOS) devices, or the like) and/or passive components (e.g., resistors, capacitors, inductors or the like) formed therein. In some embodiments, such active components and passive components are formed in a front-end-of-line (FEOL) process. In an alternative embodiment, the semiconductor substrate 110 is a bulk silicon substrate, such as a bulk substrate of monocrystalline silicon, a doped silicon substrate, an undoped silicon substrate, or a silicon-on-insulator (SOI) substrate, where the dopant of the doped silicon substrate may be an N-type dopant, a P-type dopant or a combination thereof. The disclosure is not limited thereto. Alternatively, the semiconductor substrate 110 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. For example, the semiconductor substrate 110 has an active surface (e.g., the frontside surface S110f), sometimes called a top side, and a non-active surface (e.g., the backside surface S110b), sometimes called a bottom side.

In some embodiments, the interconnect structure 120 includes one or more inter-dielectric layers 122 and one or more patterned conductive layers 124 stacked alternately. For examples, the inter-dielectric layers 122 are silicon oxide layers, silicon nitride layers, silicon oxy-nitride layers, or dielectric layers formed by other suitable dielectric materials, and are formed by deposition or the like. For examples, the patterned conductive layers 124 are patterned copper layers or other suitable patterned metal layers, and are formed by electroplating or deposition. However, the disclosure is not limited thereto. Alternatively, the patterned conductive layers 124 may be formed by a single or dual-damascene method. The number of the inter-dielectric layers 122 and the number of the patterned conductive layers 124 may be less than or more than what is depicted in FIG. 1, and may be designated and selected based on the demand and/or design layout; the disclosure is not specifically limited thereto. In some embodiments, the interconnect structure 120 is formed in a back-end-of-line (BEOL) process. In certain embodiments, as shown in FIG. 1, the patterned conductive layers 124 are sandwiched between the inter-dielectric layers 122, where a surface of the outermost layer of the patterned conductive layers 124 is exposed by an outermost layer of the inter-dielectric layers 122 to connect to later formed component(s) for electrical connection (e.g. with the conductive pads 130), and a surface of an innermost layer of the patterned conductive layers 124 is exposed by an innermost layer of the inter-dielectric layers 122 and electrically connected to the active components and/or passive components included in the semiconductor substrate 110. In other words, the interconnect structure 120 may be referred to as a routing structure for providing the routing functions to the components formed in the semiconductor substrate 110.

In some embodiments, the conductive pads 130 are formed on the interconnect structure 120 and over the semiconductor substrate 110, and sidewalls and illustrated top surfaces S130t of the conductive pads 130 are wrapped around by (e.g., in physical contact with) the dielectric layer 140. As shown in FIG. 1, the conductive pads 130 are completely covered by the dielectric layer 140. In some embodiments, the conductive pads 130 each physically contact the surface of the outermost layer of the patterned conductive layers 124 exposed by the outermost layer of the inter-dielectric layers 122. Through the interconnect structure 120, the conductive pads 130 are electrically connected to the active components and/or passive components included in the semiconductor substrate 110. For simplification, only four conductive pads 130 are presented in the semiconductor die 100 as shown in FIG. 1 for illustrative purposes, however it should be noted that more than four conductive pads 130 may be formed; the disclosure is not limited thereto.

In some embodiments, the conductive pads 130 are formed by photolithography, plating, photoresist stripping processes or any other suitable method. The plating process may include an electroplating plating, an electroless plating, or the like. For example, the conductive pads 130 is formed by, but not limited to, conformally forming a seed layer (not shown) over the interconnect structure 120, forming a mask pattern (not shown) covering the seed layer over the interconnect structure 120 with opening holes (not shown) corresponding to the surface of the outermost layer of the patterned conductive layers 124 exposed by the outermost layer of the inter-dielectric layers 122, forming a metallic material over the seed layer exposed by the opening holes and to fill the opening holes formed in the mask pattern by electroplating or deposition, removing the mask pattern, and removing the seed layer exposed by the metallic material so to form the conductive pads 130. The seed layer may be referred to as a metal or metallic layer, which can be a single layer or a composite layer including a plurality of sub-layers formed of different materials. The material of the seed layer may include titanium, copper, molybdenum, tungsten, titanium nitride, titanium tungsten, combinations thereof, or the like, which may be formed using, for example, sputtering, physical vapor deposition (PVD), or the like. For example, the seed layer may be or include a titanium layer and a copper layer over the titanium layer. The seed layer may be removed by an etching process, such a dry etching process, a wet etching process, or the combination thereof. The mask pattern may be removed by acceptable ashing process and/or photoresist stripping process, such as using an oxygen plasma or the like. In one embodiment, the material of the conductive pads 130 includes a metal material such as copper, copper alloys, aluminum, aluminum alloys, molybdenum, tungsten, titanium, tantalum, or the like. For example, the conductive pads 130 may be made of copper.

In some embodiments, in a vertical projection on the frontside surface S110f of the semiconductor substrate 110 along the (stacking) direction Z of the semiconductor substrate 110, the interconnect structure 120, the conductive pads 130 and the dielectric layer 140, the conductive pads 130 may independently be in a circle-shape, an ellipse-shape, a triangle-shape, a rectangle-shape, a polygonal shape, a pre-determined shape (e.g., a main body with branches) or the like. The shape of the conductive pads 130 is not limited in the disclosure. The shape and number of the conductive pads 130 may be designated and selected based on the demand and design layout. In the disclosure, the conductive pads 130 may be referred to as bonding pads or top metals of the semiconductor die 100.

In some embodiments, as shown in FIG. 1, the dielectric layer 140 is formed on the interconnect structure 120 to cover the conductive pads 130, where the conductive pads 130 are embedded inside the dielectric layer 140, and the interconnect structure 120 exposed by the conductive pads 130 is covered by and in contact with the dielectric layer 140. As shown in FIG. 1, the dielectric layer 140 has a substantially planar surface (e.g., a surface S140t), for example. In certain embodiments, the surface S140t of the dielectric layer 140 is leveled and may have a high degree of planarity and flatness, which is beneficial for a sequential process. In some embodiments, the dielectric layer 140 includes a polyimide (PI) layer, a polybenzoxazole (PBO) layer, a silicon dioxide based (non-organic) layer or other suitable polymer (or organic) layer, and is formed by deposition or the like. For example, the dielectric layer 140 may be made of silicon oxide or silicon oxynitride. The disclosure is not limited thereto. In addition, the disclosure does not specifically limit a thickness of the dielectric layer 140 as long as the dielectric layer 140 can embed the conductive pads 130 and maintain its high degree of planarity and flatness. The dielectric layer 140 may be referred to as a passivation layer for providing protection to the conductive pads 130. In addition, the surface S140t of the dielectric layer 140 may be referred to as a front surface of the semiconductor die 100, and the backside surface S110b of the semiconductor substrate 110 may be referred to as a bottom surface of the semiconductor die 100.

In some embodiments, the semiconductor die 200 includes a semiconductor substrate 210, an interconnect structure 220 disposed on the semiconductor substrate 210, a plurality of conductive pads 230 disposed on and electrically coupled to the interconnect structure 220, and a dielectric layer 240 disposed on and covering the conductive pads 230 and the interconnect structure 220 exposed by the conductive pads 230. As shown in FIG. 1, the semiconductor substrate 210 has a frontside surface S210f and a backside surface S210b opposite to the frontside surface S210f, and the interconnect structure 220 is located on the frontside surface S210f of the semiconductor substrate 210, where the interconnect structure 220 is sandwiched between the semiconductor substrate 210 and the conductive pads 230 and sandwiched between the semiconductor substrate 210 and the dielectric layer 240, for example.

In some embodiments, the semiconductor substrate 210 is a silicon substrate including active components (e.g., transistors and/or memories such as NMOS and/or PMOS devices, or the like) and/or passive components (e.g., resistors, capacitors, inductors or the like) formed therein. In some embodiments, such active components and passive components are formed in the FEOL process. In an alternative embodiment, the semiconductor substrate 210 is a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto. Alternatively, the semiconductor substrate 210 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. For example, the semiconductor substrate 210 has an active surface (e.g., the frontside surface S210f), sometimes called a top side, and a non-active surface (e.g., the backside surface S210b), sometimes called a bottom side.

In some embodiments, the interconnect structure 220 includes one or more inter-dielectric layers 222 and one or more patterned conductive layers 224 stacked alternately. For examples, the inter-dielectric layers 222 are silicon oxide layers, silicon nitride layers, silicon oxy-nitride layers, or dielectric layers formed by other suitable dielectric materials, and are formed by deposition or the like. For examples, the patterned conductive layers 224 are patterned copper layers or other suitable patterned metal layers, and are formed by electroplating or deposition. However, the disclosure is not limited thereto. Alternatively, the patterned conductive layers 224 may be formed by a single or dual-damascene method. The number of the inter-dielectric layers 222 and the number of the patterned conductive layers 224 may be less than or more than what is depicted in FIG. 1, and may be designated and selected based on the demand and/or design layout; the disclosure is not specifically limited thereto. In some embodiments, the interconnect structure 220 is formed in the BEOL process. In certain embodiments, as shown in FIG. 1, the patterned conductive layers 224 are sandwiched between the inter-dielectric layers 222, where a surface of the outermost layer of the patterned conductive layers 224 is exposed by an outermost layer of the inter-dielectric layers 222 to connect to later formed component(s) for electrical connection (e.g. with the conductive pads 230), and a surface of an innermost layer of the patterned conductive layers 224 is exposed by an innermost layer of the inter-dielectric layers 222 and electrically connected to the active components and/or passive components included in the semiconductor substrate 210. In other words, the interconnect structure 220 may be referred to as a routing structure for providing the routing functions to the components formed in the semiconductor substrate 210.

In some embodiments, the conductive pads 230 are formed on the interconnect structure 220 and over the semiconductor substrate 210, and sidewalls and illustrated top surfaces S230t of the conductive pads 230 are wrapped around by (e.g., in physical contact with) the dielectric layer 240. As shown in FIG. 1, the conductive pads 230 are completely covered by the dielectric layer 240. In some embodiments, the conductive pads 230 each physically contact the surface of the outermost layer of the patterned conductive layers 224 exposed by the outermost layer of the inter-dielectric layers 222. Through the interconnect structure 220, the conductive pads 230 are electrically connected to the active components and/or passive components included in the semiconductor substrate 210. For simplification, only four conductive pads 230 are presented in the semiconductor die 200 as shown in FIG. 1 for illustrative purposes, however it should be noted that more than four conductive pads 230 may be formed; the disclosure is not limited thereto.

In some embodiments, the conductive pads 230 are formed by photolithography, plating, photoresist stripping processes or any other suitable method. The plating process may include an electroplating plating, an electroless plating, or the like. For example, the conductive pads 230 is formed by, but not limited to, conformally forming a seed layer (not shown) over the interconnect structure 220, forming a mask pattern (not shown) covering the seed layer over the interconnect structure 220 with opening holes (not shown) corresponding to the surface of the outermost layer of the patterned conductive layers 224 exposed by the outermost layer of the inter-dielectric layers 222, forming a metallic material over the seed layer exposed by the opening holes and to fill the opening holes formed in the mask pattern by electroplating or deposition, removing the mask pattern, and removing the seed layer exposed by the metallic material so to form the conductive pads 230. The seed layer may be referred to as a metal or metallic layer, which can be a single layer or a composite layer including a plurality of sub-layers formed of different materials. The material of the seed layer may include titanium, copper, molybdenum, tungsten, titanium nitride, titanium tungsten, combinations thereof, or the like, which may be formed using, for example, sputtering, PVD, or the like. For example, the seed layer may be or include a titanium layer and a copper layer over the titanium layer. The seed layer may be removed by an etching process, such a dry etching process, a wet etching process, or the combination thereof. The mask pattern may be removed by acceptable ashing process and/or photoresist stripping process, such as using an oxygen plasma or the like. In one embodiment, the material of the conductive pads 230 includes a metal material such as copper, copper alloys, aluminum, aluminum alloys, molybdenum, tungsten, titanium, tantalum, or the like. For example, the conductive pads 230 may be made of aluminum.

In some embodiments, in a vertical projection on the frontside surface S210f of the semiconductor substrate 210 along the (stacking) direction Z of the semiconductor substrate 210, the interconnect structure 220, the conductive pads 230 and the dielectric layer 240, the conductive pads 230 may independently be in a circle-shape, an ellipse-shape, a triangle-shape, a rectangle-shape, a polygonal shape, a pre-determined shape (e.g., a main body with branches) or the like. The shape of the conductive pads 230 is not limited in the disclosure. The shape and number of the conductive pads 230 may be designated and selected based on the demand and design layout. In the disclosure, the conductive pads 230 may be referred to as bonding pads or top metals of the semiconductor die 200.

In some embodiments, as shown in FIG. 1, the dielectric layer 240 is formed on the interconnect structure 220 to cover the conductive pads 230, where the conductive pads 230 are embedded inside the dielectric layer 240, where the interconnect structure 220 exposed by the conductive pads 230 is covered by and in contact with the dielectric layer 240. As shown in FIG. 1, the dielectric layer 240 has a substantially planar surface (e.g., a surface S240t), for example. In certain embodiments, the surface S240t of the dielectric layer 240 is leveled and may have a high degree of planarity and flatness, which is beneficial for a sequential process. In some embodiments, the dielectric layer 240 includes a PI layer, a PBO layer, a silicon dioxide based (non-organic) layer or other suitable polymer (or organic) layer, and is formed by deposition or the like. For example, the dielectric layer 240 may be made of silicon oxide or silicon oxynitride. The disclosure is not limited thereto. In addition, the disclosure does not specifically limit a thickness of the dielectric layer 240 as long as the dielectric layer 240 can embed the conductive pads 230 and maintain its high degree of planarity and flatness. The dielectric layer 240 may be referred to as a passivation layer for providing protection to the conductive pads 230. In addition, the surface S240t of the dielectric layer 240 may be referred to as a front surface of the semiconductor die 200, and the backside surface S210b may be referred to as a bottom surface of the semiconductor die 200.

It is appreciated that, in some embodiments, the semiconductor dies 100, 200 independently described herein may be referred to as a semiconductor chip or an integrated circuit (IC). In some embodiments, the semiconductor dies 100, 200 independently are a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor dies 100, 200 independently may be or include a digital chip, an analog chip or a mixed signal chip. The semiconductor dies 100, 200 independently may be a chip or an IC of combination-type, such as a WiFi chip simultaneously including both of a RF chip and a digital chip.

In alternative embodiments, each of the semiconductor dies 100, 200 independently includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash, a wide I/O memory (WIO) die, a high bandwidth memory (HBM) die, the like, etc.) with or without a controller. In alternative embodiments, the semiconductor dies 100, 200 independently are an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), etc. ; a combination thereof; or the like. In other alternative embodiments, the semiconductor dies 100, 200 independently are an electrical and/or optical input/output (I/O) interface die, an integrated passives (IPD) die, a voltage regulator (VR) die, a local silicon interconnect (LSI) die with or without deep trench capacitor (DTC) features, a local silicon interconnect die with multi-tier functions such as electrical and/or optical network circuit interfaces, IPD, VR, DTC, or the like. The type of the semiconductor dies 100, 200 independently may be selected and designated based on the demand and design requirement, and thus is not specifically limited in the disclosure.

In some embodiments, the types of the semiconductor dies 100, 200 are different. In alternative embodiments of which multiple semiconductor dies 100 and/or multiple semiconductor dies 200 are included, the types of some of the semiconductor dies 100, 200 are different, while the types of some of the semiconductor dies 100, 200 are identical. In further alternative embodiments, the types of the semiconductor dies 100, 200 are identical. In some embodiments, the sizes of the semiconductor dies 100, 200 are the different. In alterative embodiments of which multiple semiconductor dies 100 and/or multiple semiconductor dies 200 are included, the sizes of some of the semiconductor dies 100, 200 are different, while the sizes of some of the semiconductor dies 100, 200 are identical. In further alternative embodiments, the sizes of the semiconductor dies 100, 200 are identical. In some embodiments, the shapes of the semiconductor dies 100, 200 are different. In alternative embodiments of which multiple semiconductor dies 100 and/or multiple semiconductor dies 200 are included, the shapes of some of the semiconductor dies 100, 200 are different, while the shapes of some of the semiconductor dies 100, 200 are identical. In further alternative embodiments, the shapes of the semiconductor dies 100, 200 are identical. The types, sizes and shapes of each of the semiconductor dies 100, 200 are independent from each other, and may be selected and designed based on the demand and design layout, the disclosure is not limited thereto. For example, one of the semiconductor dies 100 and 200 may be formed by advanced process or be a special function chip than the other one of the semiconductor dies 100 and 200.

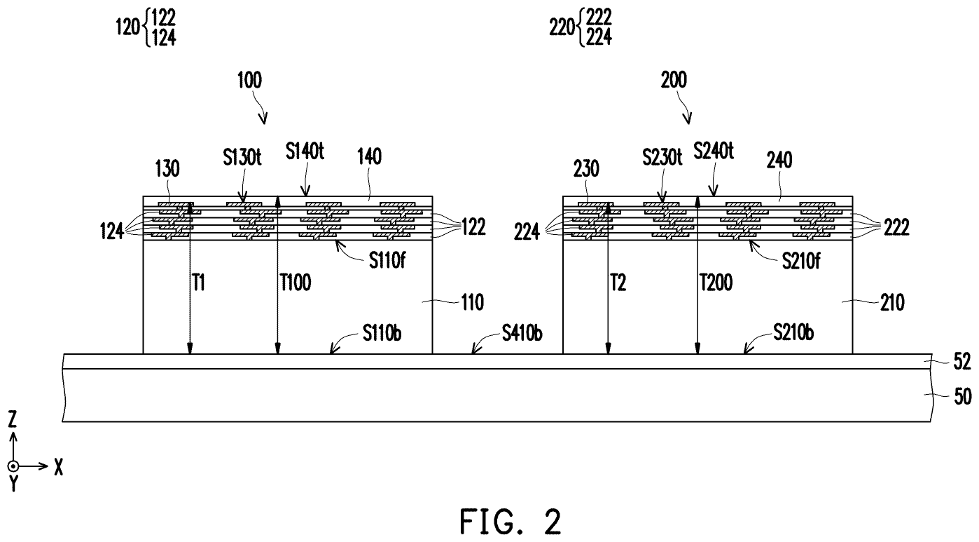

Referring to FIG. 2, in some embodiments, a carrier 50 is provided, and the semiconductor dies 100, 200 are placed onto the carrier 50. In some embodiments, the carrier 50 may be a glass carrier or any suitable carrier for carrying a semiconductor wafer or a reconstituted wafer for the manufacturing method of the semiconductor device. In some embodiments, the carrier 50 is coated with a dielectric layer 52 (as shown in FIG. 2).

The dielectric layer 52 may be a single layer or include a plurality of stacked dielectric sublayers. The dielectric layer 52 may be formed by, but not limited to, conformally forming a blanket layer of the material used for forming the dielectric layer 52 over the carrier 50. In a non-limiting example, the material of the dielectric layer 52 may include inorganic materials such as silicon oxide, silicon oxynitride, silicon nitride, silicon carbonitride or silicon oxy-carbonitride; other suitable dielectric layer; or a combination thereof. For example, the dielectric layer 52 may be made of silicon oxide or silicon oxynitride. The dielectric layer 52 may be formed by suitable fabrication techniques such as spin-on coating, chemical vapor deposition (CVD), atomic layer deposition (ALD), PVD, or the like. For example, the dielectric layer 52 has an illustrated top surface with a high degree of coplanarity, which is beneficial for a sequential process (e.g., a bonding process).

Continued on FIG. 2, in some embodiments, the semiconductor dies 100, 200 are placed on the dielectric layer 52 over the carrier 50 by pick-and-place process. In some embodiments, after placing the semiconductor dies 100, 200 over the dielectric layer 52, the semiconductor dies 100, 200 are bonded to the dielectric layer 52 by a fusion bonding. The fusion bonding may include a dielectric-to-dielectric bonding (such as a ‘oxide’-to-‘silicon’ bonding or a ‘nitride’-to-‘silicon’ bonding). In such embodiments, a bonding interface IF1 including a dielectric-to-dielectric bonding interface (such as a ‘oxide’-to-‘silicon’ bonding interface or a ‘nitride’-to-‘silicon’ bonding interface) exists between the semiconductor substrate 110 of the semiconductor die 100 and the dielectric layer 52, and a bonding interface IF2 including a dielectric-to-dielectric bonding interface (such as a ‘oxide’-to-‘silicon’ bonding interface or a ‘nitride’-to-‘silicon’ bonding interface) exists between the semiconductor substrate 210 of the semiconductor die 200 and the dielectric layer 52. The semiconductor die 100 and the semiconductor 200 are bonded to the dielectric layer 52 over the carrier 50 by a chip-on-wafer (CoW) bonding.

For example, the semiconductor dies 100, 200 are disposed on the dielectric layer 52 by a lateral distance therebetween, where the lateral distance is non-zero. In some embodiments, a thickness T100 of the semiconductor die 100 and a thickness T200 of the semiconductor die 200 are substantially the same, as shown in FIG. 2. Alternatively, the thickness T100 of the semiconductor die 100 and the thickness T200 of the semiconductor die 200 may be different from each other. In a non-limiting example, the thickness T100 of the semiconductor die 100 is greater than the thickness T200 of the semiconductor die 200. In other non-limiting example, the thickness T100 of the semiconductor die 100 is less than the thickness T200 of the semiconductor die 200. In some embodiments, a distance T1 between the surface S130t of the conductive pads 130 of the semiconductor die 100 and the illustrated top surface (not labeled) of the dielectric layer 52 is less than a distance T2 between the surface S230t of the conductive pads 230 of the semiconductor die 200 and the illustrated top surface (not labeled) of the dielectric layer 52, as shown in FIG. 2. Alternatively, a distance T1 between the surface S130t of the conductive pads 130 of the semiconductor die 100 and the illustrated top surface (not labeled) of the dielectric layer 52 may be greater than a distance T2 between the surface S230t of the conductive pads 230 of the semiconductor die 200 and the illustrated top surface (not labeled) of the dielectric layer 52. Or, the distance T1 between the surface S130t of the conductive pads 130 of the semiconductor die 100 and the illustrated top surface (not labeled) of the dielectric layer 52 may be substantially the same as the distance T2 between the surface S230t of the conductive pads 230 of the semiconductor die 200 and the illustrated top surface (not labeled) of the dielectric layer 52. The disclosure is not limited thereto.

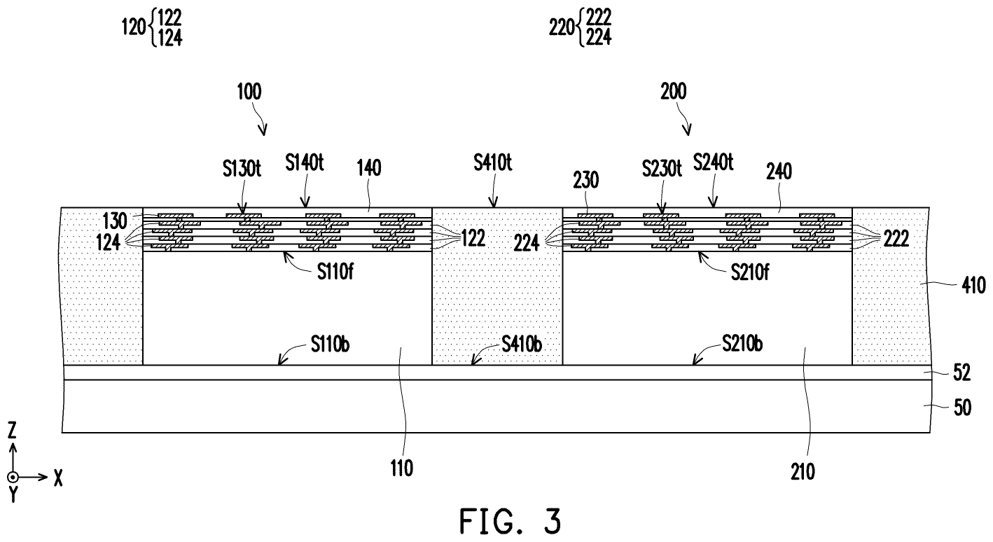

Referring to FIG. 3, in some embodiments, an insulating encapsulant 410 is formed to encapsulate the semiconductor dies 100, 200. For example, the insulating encapsulant 410 laterally encapsulates the semiconductor dies 100, 200 and covers the dielectric layer 52 exposed by the semiconductor dies 100, 200, where the surface S140t of the dielectric layer 140 of the semiconductor dies 100 and the surface S240t of the dielectric layer 240 of the semiconductor dies 200 are accessibly revealed by the insulating encapsulant 410, while the conductive pads 130 of the semiconductor die 100 and the conductive pads 230 of the semiconductor die 200 are still embedded inside the dielectric layer 140 and the dielectric layer 240, respectively. In some embodiments, a surface S410t of the insulating encapsulant 410 is substantially level with the surface S140t of the dielectric layer 140 of the semiconductor dies 100 and the surface S240t of the dielectric layer 240 of the semiconductor dies 200, and a surface S410b of the insulating encapsulant 410 is in physical contact with the dielectric layer 52, where the surface S410b is opposite to the surface S410t in the direction Z. In other words, the surface S410t of the insulating encapsulant 410 is substantially coplanar to the surface S140t of the dielectric layer 140 of the semiconductor dies 100 and the surface S240t of the dielectric layer 240 of the semiconductor dies 200.

The formation of the insulating encapsulant 410 may include by, but not limited to, forming an insulating encapsulant material (not shown) over the carrier 50 to cover the semiconductor dies 100, 200; and performing a planarizing process on the insulating encapsulant material to form the insulating encapsulant 410. For example, the insulating encapsulant material is conformally formed on the semiconductor dies 100, 200, where the semiconductor dies 100, 200 and the illustrated top surface of the dielectric layer 52 exposed by the semiconductor dies 100, 200 are covered by the insulating encapsulant material. In some embodiments, the surface S140t and a sidewall of the semiconductor die 100 and the surface S240t and a sidewall of the semiconductor die 200 are physically contacted with and encapsulated by the insulating encapsulant material. The insulating encapsulant material may be made of a dielectric material (such as an oxide (e.g. silicon oxide), a nitride (e.g. silicon nitride), tetra-ethyl-ortho-silicate (TEOS), or the like) or any suitable insulating materials for gap fill, and may be formed by deposition (such as a CVD process). After forming the insulating encapsulant material over the carrier 50, the planarizing process is performed on the insulating encapsulant material to form the insulating encapsulant 410 laterally encapsulating the semiconductor dies 100, 200. For example, a portion of the insulating encapsulant material is removed to form the insulating encapsulant 410 having the surface S410t (may referred to as a top surface) accessibly exposing the semiconductor dies 100 and 200, where the surface S410t is a flat and planar surface.

During the planarizing process, the dielectric layer 140 of the semiconductor die 100 and/or the dielectric layer 240 of the semiconductor die 200 may further be planarized. In some embodiments, the planarizing process may include a grinding process, etching process, a chemical mechanical polishing (CMP) process, or combinations thereof. The etching process may include a dry etch, a wet etch or a combination thereof. After the planarizing process, a cleaning process may be optionally performed, for example to clean and remove the residue generated from the planarizing process. However, the disclosure is not limited thereto, and the planarizing process may be performed through any other suitable method.

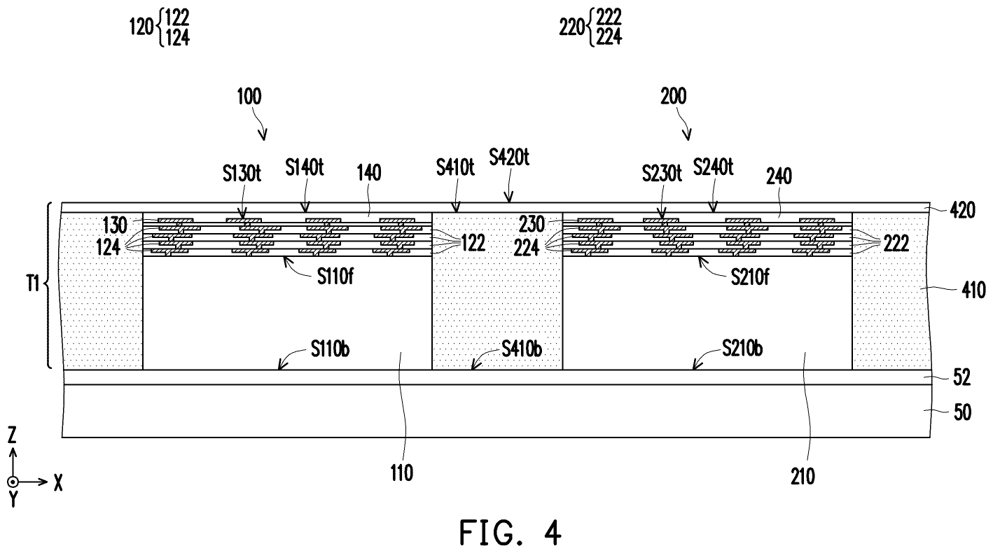

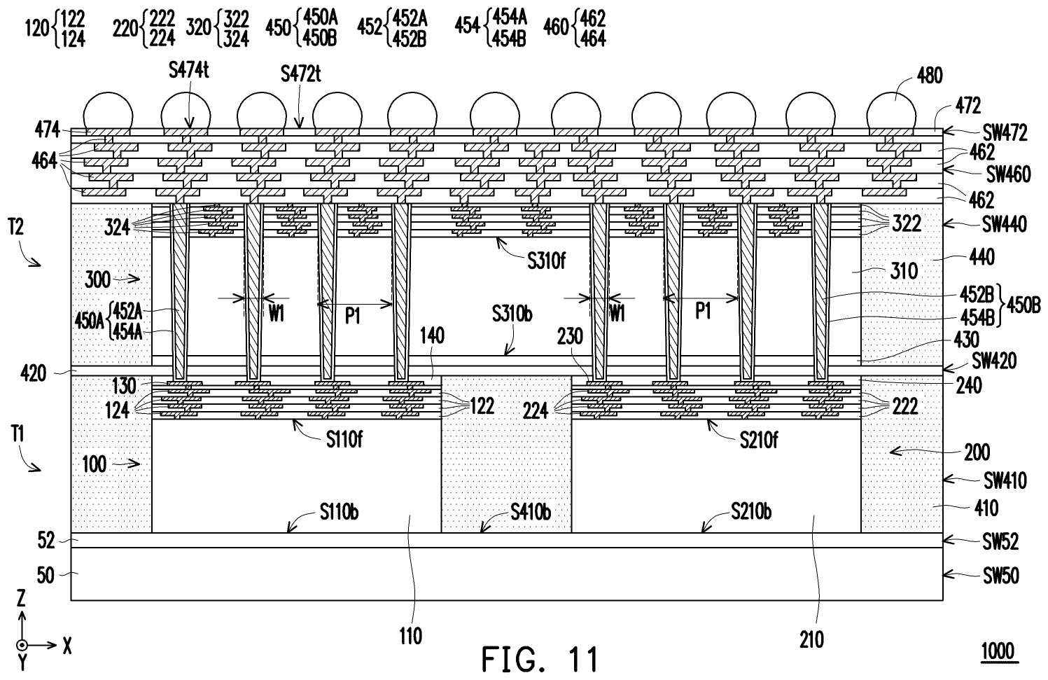

Referring to FIG. 4, in some embodiments, a bonding layer 420 is formed over the semiconductor dies 100, 200 and the insulating encapsulant 410. For example, the bonding layer 420 is disposed on (e.g., in physical contact with) the surface S140t of the semiconductor die 100, the surface S240t of the semiconductor die 200 and the surface S410t of the insulating encapsulant 410. The bonding layer 420 may be referred to as a dielectric layer or a bonding dielectric layer. The bonding layer 420 may be a single layer or include a plurality of stacked dielectric sublayers. The bonding layer 420 may be formed by, but not limited to, conformally forming a blanket layer of the material used for forming the bonding layer 420 over the structure depicted in FIG. 3. In a non-limiting example, the material of the bonding layer 420 may include inorganic materials such as silicon oxide, silicon oxynitride, silicon nitride, silicon carbonitride or silicon oxy-carbonitride; other suitable dielectric layer; or a combination thereof. For example, the bonding layer 420 may be made of silicon oxide or silicon oxynitride. The bonding layer 420 may be formed by suitable fabrication techniques such as spin-on coating, CVD, atomic layer deposition (ALD), PVD, or the like. For example, the bonding layer 420 has a surface S420t and a surface S420b opposite to the surface S420t, where the surface S420b may be referred to as an illustrated bottom surface of the bonding layer 420, and the surface S420t may be referred to as an illustrated top surface of the bonding layer 420 and may be level and may have a high degree of coplanarity, which is beneficial for a sequential process (e.g., a bonding process), as shown in FIG. 4. Up to here, a first tier of the semiconductor device 1000 (FIG. 11) is manufactured, where the first tier includes the semiconductor die 100, the semiconductor die 200, the insulating encapsulant 410 and the bonding layer 420.

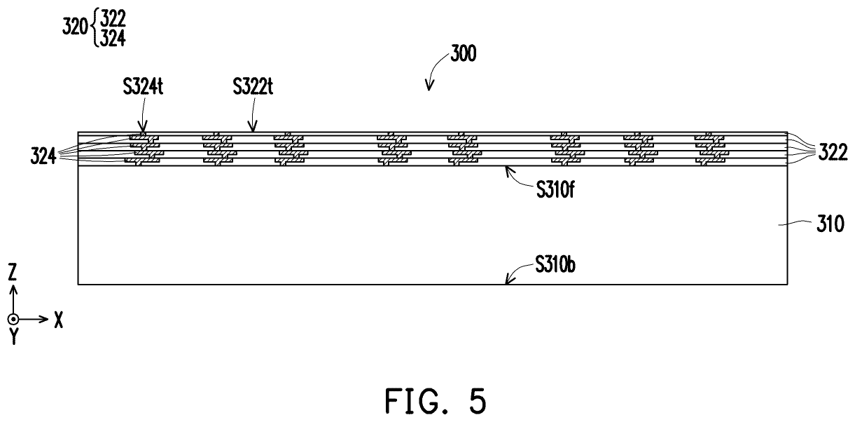

Referring to FIG. 5, in some embodiments, at least one semiconductor die 300 is provided. For illustrative purposes and simplicity, the at least one semiconductor die 300 includes only one semiconductor die 300 as shown in FIG. 5; however, the disclosure is not limited thereto. The number of the semiconductor die 300 may be more than one, which may be selected and/or designated based on the demand and/or design layout.

In some embodiments, the semiconductor die 300 includes a semiconductor substrate 310 and an interconnect structure 320 disposed on the semiconductor substrate 310. As shown in FIG. 5, the semiconductor substrate 310 has a frontside surface S310f and a backside surface S310b opposite to the frontside surface S310f, and the interconnect structure 320 is located on the frontside surface S310f of the semiconductor substrate 310.

In some embodiments, the semiconductor substrate 310 is a silicon substrate including active components (e.g., transistors and/or memories such as NMOS and/or PMOS devices, or the like) and/or passive components (e.g., resistors, capacitors, inductors or the like) formed therein. In some embodiments, such active components and passive components are formed in the FEOL process. In an alternative embodiment, the semiconductor substrate 310 is a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto. Alternatively, the semiconductor substrate 310 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. For example, the semiconductor substrate 310 has an active surface (e.g., the frontside surface S310f), sometimes called a top side, and a non-active surface (e.g., the backside surface S310b), sometimes called a bottom side.

In some embodiments, the interconnect structure 320 includes one or more inter-dielectric layers 322 and one or more patterned conductive layers 324 stacked alternately. For examples, the inter-dielectric layers 322 are silicon oxide layers, silicon nitride layers, silicon oxy-nitride layers, or dielectric layers formed by other suitable dielectric materials, and are formed by deposition or the like. For examples, the patterned conductive layers 324 are patterned copper layers or other suitable patterned metal layers, and are formed by electroplating or deposition. However, the disclosure is not limited thereto. Alternatively, the patterned conductive layers 324 may be formed by a single or dual-damascene method. The number of the inter-dielectric layers 322 and the number of the patterned conductive layers 324 may be less than or more than what is depicted in FIG. 5, and may be designated and selected based on the demand and/or design layout; the disclosure is not specifically limited thereto. In some embodiments, the interconnect structure 320 is formed in the BEOL process. In certain embodiments, as shown in FIG. 5, the patterned conductive layers 324 are sandwiched between the inter-dielectric layers 322, where a surface of the outermost layer of the patterned conductive layers 324 is exposed by an outermost layer of the inter-dielectric layers 322 to connect to later formed component(s) for electrical connection, and a surface of an innermost layer of the patterned conductive layers 324 is exposed by an innermost layer of the inter-dielectric layers 322 and electrically connected to the active components and/or passive components included in the semiconductor substrate 310. In other words, the interconnect structure 320 may be referred to as a routing structure for providing the routing functions to the components formed in the semiconductor substrate 310.

It is appreciated that, in some embodiments, the semiconductor die 300 described herein may be referred to as a semiconductor chip or an integrated circuit (IC). In some embodiments, the semiconductor die 300 is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor die 300 may be or include a digital chip, an analog chip or a mixed signal chip. The semiconductor die 300 may be a chip or an IC of combination-type, such as a WiFi chip simultaneously including both of a RF chip and a digital chip.

In alternative embodiments, the semiconductor die 300 includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash, a wide I/O memory (WIO) die, a high bandwidth memory (HBM) die, the like, etc.) with or without a controller. In alternative embodiments, the semiconductor die 300 is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), etc. ; a combination thereof; or the like. In other alternative embodiments, the semiconductor die 300 is an electrical and/or optical input/output (I/O) interface die, an integrated passives (IPD) die, a voltage regulator (VR) die, a local silicon interconnect (LSI) die with or without deep trench capacitor (DTC) features, a local silicon interconnect die with multi-tier functions such as electrical and/or optical network circuit interfaces, IPD, VR, DTC, or the like. The type of the semiconductor die 300 may be selected and designated based on the demand and design requirement, and thus is not specifically limited in the disclosure. The types, sizes and shapes of the semiconductor die 300 individually may be the same or different from the types, sizes and shapes of each of the semiconductor dies 100, 200, and may be selected and designed based on the demand and design layout, the disclosure is not limited thereto.

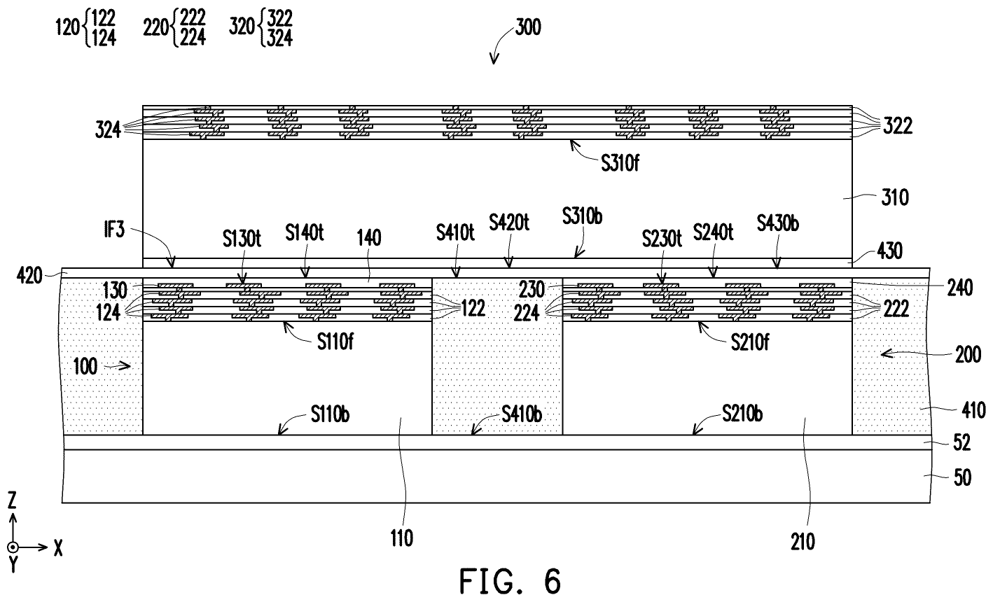

Referring to FIG. 5 and FIG. 6 together, in some embodiments, the semiconductor die 300 is placed on the structure depicted in FIG. 4 by pick-and-place process. Before placing the semiconductor die 300 over the structure depicted in FIG. 4, a bonding layer 430 is formed on the surface S310b of the semiconductor die 300. The details, formation and material of the bonding layer 430 may be similar to or substantially identical to the details, formation and material of the bonding layer 420 described in FIG. 4, and thus are not repeated herein for simplicity. For example, the bonding layer 430 may be made of silicon oxide or silicon oxynitride. For example, the bonding layer 430 has a surface S430t and a surface S430b opposite to the surface S430t, where the surface S430t may be referred to as an illustrated top surface of the bonding layer 430 that is in (physical) contact with the semiconductor substrate 310, and the surface S430b may be referred to as an illustrated bottom surface of the bonding layer 430 and may have a high degree of coplanarity that is beneficial for a sequential process (e.g., a bonding process), as shown in FIG. 6.

Continued on FIG. 6, after placing the semiconductor die 300 over the structure depicted in FIG. 4, a bonding process may be performed to bond the semiconductor die 300 to the first tier of the semiconductor device 1000 (FIG. 11) by a CoW bonding. As shown in FIG. 6, the semiconductor die 300 may be bonded to the semiconductor dies 100, 200 by connecting the bonding layer 430 disposed on the semiconductor die 300 and the bonding layer 420 disposed on the semiconductor dies 100, 200. For example, the bonding layer 430 is bonded to the bonding layer 420 by a fusion bonding. The fusion bonding may include a dielectric-to-dielectric bonding (such as a ‘oxide’-to-‘oxide’ bonding, a ‘nitride’-to-‘nitride’ bonding or a ‘nitride’-to-‘oxide’ bonding). In such embodiments, a bonding interface IF3 including a dielectric-to-dielectric bonding interface (such as a ‘oxide’-to-‘oxide’ bonding interface, a ‘nitride’-to-‘nitride’ bonding interface or a ‘nitride’-to-‘oxide’ bonding interface) exists between the bonding layer 420 and the bonding layer 430.

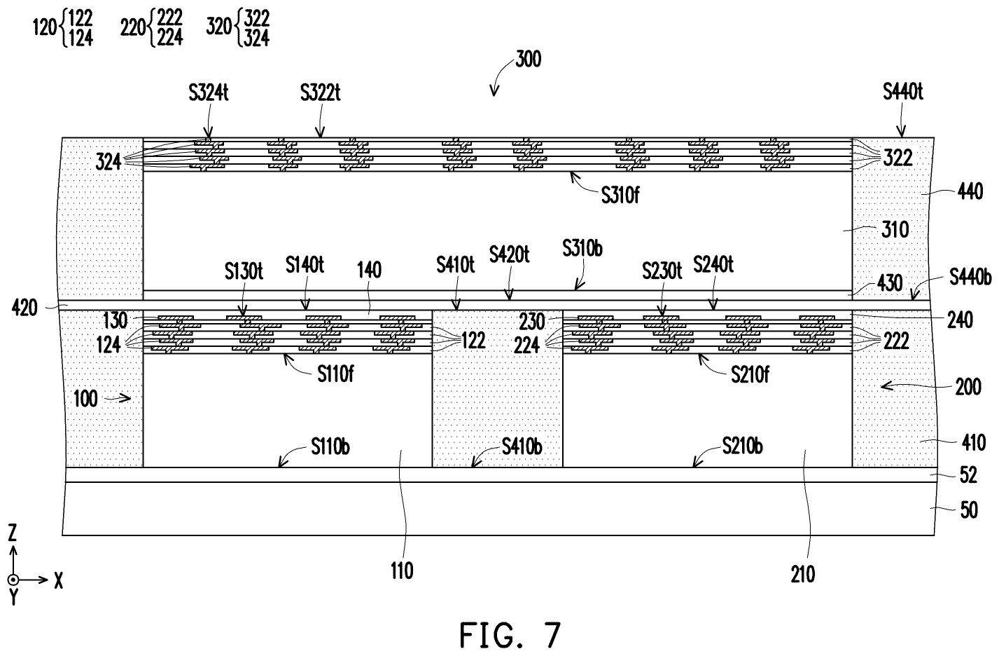

Referring to FIG. 7, in some embodiments, an insulating encapsulant 440 is formed to encapsulate the semiconductor die 300. For example, the insulating encapsulant 440 laterally encapsulates the semiconductor die 300 and covers the bonding layer 420 exposed by the semiconductor die 300, where a surface S322t of the outermost layer of the inter-dielectric layers 322 and a surface S324t of the outermost layer of the patterned conductive layer 324 are accessibly revealed by the insulating encapsulant 440. In some embodiments, a surface S440t of the insulating encapsulant 440 is substantially level with the surface S322t of the outermost layer of the inter-dielectric layers 322 and the surface S324t of the outermost layer of the patterned conductive layer 324, and a surface S440b of the insulating encapsulant 440 is in physical contact with the bonding layer 420 exposed by the semiconductor die 300, where the surface S440b is opposite to the surface S440t in the direction Z. In other words, the surface S440t of the insulating encapsulant 440 is substantially coplanar to the surface S322t of the outermost layer of the inter-dielectric layers 322 and the surface S324t of the outermost layer of the patterned conductive layer 324. The details, formation and material of the insulating encapsulant 440 may be similar to or substantially identical to the details, formation and material of the insulating encapsulant 410 described in FIG. 3, and thus are not repeated herein for simplicity.

Referring to FIG. 8, in some embodiments, a plurality of through vias 450 (each including a conductive via 452 (e.g., 452A, 452B) and a barrier liner 454 (e.g., 454A, 454B) lining a bottom and a sidewall of the conductive via 452 (e.g., 452A, 452B)) are formed in the structure depicted in FIG. 7. The plurality of through vias 450 may include a plurality of through vias 450A (each including 452A and 454A) disposed over and electrically coupled to the semiconductor die 100 and a plurality of through vias 450B (each including 452B and 454B) disposed over and electrically coupled to the semiconductor die 200, as shown in FIG. 8. Although only four through vias 450A and four through vias 450B are shown in FIG. 8 for illustrative purposes, the number of the through vias 450A and the number of the through vias 450B are not limited to FIG. 8. The number of the through vias 450A and the number of the through vias 450B may be selected and/or designated based on the demand and/or the design layout, the disclosure is not limited thereto. As shown in FIG. 8, the through vias 450A of the through vias 450 may penetrate through the semiconductor die 300 and the bonding layer 430 and extended into the semiconductor die 100 to be in (physical) contact with the conductive pads 130, and the through vias 450B of the through vias 450 may penetrate through the semiconductor die 300 and the bonding layer 430 and extended into the semiconductor die 200 to be in (physical) contact with the conductive pads 230, so that the through vias 450A are electrically coupled to the conductive pads 130 of the semiconductor die 100 and the through vias 450B are electrically coupled to the conductive pads 230 of the semiconductor die 200. In some embodiments, as shown in FIG. 8, the through vias 450A penetrate through the dielectric layer 140 to be in contact with the conductive pads 130, and the through vias 450B penetrate through the dielectric layer 240 to be in contact with the conductive pads 230.

The formation of the through vias 450 (including 450A and 450B) may include by, but not limited to, patterning the structure depicted in FIG. 7 to form a plurality of openings penetrating through the semiconductor die 300, the bonding layer 430, the bonding layer 420, the dielectric layer 140 of the semiconductor die 100 and the dielectric layer 240 of the semiconductor die 200 to respectively accessibly reveal the conductive pads 130 of the semiconductor die 100 or the conductive pads 230 of the semiconductor die 200; respectively depositing a barrier material and a conductive material in the openings; and removing the excess materials on a plane where the surface S440t of the insulating encapsulant 440 is located at so to form the through vias 450A on the semiconductor die 100 and the through vias 450B on the semiconductor die 200 simultaneously.

Alternatively, the formation of the through vias 450 (including 450A and 450B) may include by, but not limited to, patterning the structure depicted in FIG. 7 to form a plurality of first openings penetrating through the semiconductor die 300, the bonding layer 430, the bonding layer 420 and the dielectric layer 140 of the semiconductor die 100 to accessibly reveal the conductive pads 130 of the semiconductor die 100; respectively depositing a first barrier material and a first conductive material in the first openings; removing the excess materials on a plane where the surface S440t of the insulating encapsulant 440 is located at so to form the through vias 450A on the semiconductor die 100, patterning the structure depicted in FIG. 7 to form a plurality of first openings penetrating through the semiconductor die 300, the bonding layer 430, the bonding layer 420 and the dielectric layer 240 of the semiconductor die 200 to accessibly reveal the conductive pads 230 of the semiconductor die 200; respectively depositing a second barrier material and a second conductive material in the second openings; and removing the excess materials on the plane where the surface S440t of the insulating encapsulant 440 is located at so to form the through vias 450B on the semiconductor die 200. That is, the through vias 450A may be formed prior to the formation of the through vias 450B; or vice versa. The disclosure is not limited. Due to the through vias 450A and through vias 450B are formed in different steps, a compensation (if need) for overlap shift between the semiconductor dies 100 and 200 may be achieved.

The (first/second) conductive material may be copper, tungsten, aluminum, silver, combinations thereof, or the like. The (first/second) barrier material may be TiN, Ta, TaN, Ti, or the like. On the other hand, in the top (plane) view on the X-Y plane, the shape of the through vias 450 (including 450A and 450B) is long elliptical shape. However, depending on the design requirements, and the shape of the through vias 450 (including 450A and 450B) may be an oval shape, a circular shape, a rectangular shape, a polygonal shape, or combinations thereof; the disclosure is not limited thereto. The shape of the through vias 450A may be the same as the shape of the through vias 450B. Alternatively, the shape of the through vias 450A may be different from the shape of the through vias 450B. The shape of the through 450 may be selected and designated based on the demand and/or design layout, such as to fulfill the requirement of contact resistance and/or connections.

For a non-limiting example, as shown in FIG. 8 and FIG. 12, only one through via 450A, one conductive pad 130, one through via 450B and one conductive pad 230 are emphasized, and the rest of features are omitted for simplicity. As shown in FIG. 12, the through via 450A may further extend into the conductive pad 130 and stop at a position inside the conductive pad 130. For example, a portion of the through via 450A extended into the conductive pad 130 has a thickness D3, where the thickness D3 is less than or substantially equal to about 10 angstrom (Å) and is greater than or substantially equal to 0 Å. In other words, a thickness H130 of the conductive pad 130 is greater than the thickness D3, for example. For example, a minimum distance D5 between a sidewall (or edge) of the conductive pad 130 and the portion of the through via 450A extended into the conductive pad 130 is greater than about 10 Å. On the other hand, as shown in FIG. 12, the through via 450B may further extend into the conductive pad 230 and stop at a position inside the conductive pad 230. For example, a portion of the through via 450B extended into the conductive pad 230 has a thickness D4, where the thickness D4 is less than or substantially equal to about 10 Å and is greater than or substantially equal to 0 Å. In other words, a thickness H230 of the conductive pad 230 is greater than the thickness D4, for example. For example, a minimum distance D5 between a sidewall (or edge) of the conductive pad 230 and the portion of the through via 450B extended into the conductive pad 230 is greater than about 10 Å. In some embodiments, a height difference D1 between the conductive pad 130 (e.g., the surface S130) and the conductive pad 230 (e.g., the surface S230) is greater than or substantially equal to 0 Å and is less than the thickness H130 of the conductive pad 130 and the thickness H230 of the conductive pad 230. For example, the height difference D1 may be 0 Å. Alternatively, the height difference D1 may be non-zero. In some embodiments, a height difference D2 between a bottom of the through via 450A and a bottom of the through via 450B is greater than or substantially equal to 0 Å and is less than the thickness H130 of the conductive pad 130 and the thickness H230 of the conductive pad 230. For example, the height difference D2 may be 0 Å. Alternatively, the height difference D2 may be non-zero.

However, the disclosure is not limited thereto. In alternative embodiments, a metal barrier may be formed on the conductive pads 130 and/or 230. The metal barrier may be selected and designated based on the demand and/or design layout, such as to fulfill the requirement of etch stop layer, protection layer, or the like.

For example, the metal barrier 150, which is considered as a part of the semiconductor die 100, is formed over the conductive pads 130 and embedded into the dielectric layer 140, where the through vias 450A penetrate through the dielectric layer 140 and the metal barrier 150 to be in (physical) contact with the conductive pads 130. In some embodiments, the metal barrier 150 may be made of TiN or TaN. For a non-limiting example, as shown in FIG. 8 and FIG. 13, only one through via 450A, one conductive pad 130, one through via 450B, one conductive pad 230, and a metal barrier 150 are emphasized, and the rest of features are omitted for simplicity. As shown in FIG. 13, the through via 450A may penetrate through the metal barrier 150 and further extend into the conductive pad 130 and stop at a position inside the conductive pad 130. For example, a portion of the through via 450A extended into the conductive pad 130 has a thickness D3, where the thickness D3 is less than or substantially equal to about 10 Å and is greater than or substantially equal to 0 Å. In other words, a thickness H130 of the conductive pad 130 is greater than the thickness D3, for example. For example, a minimum distance D5 between a sidewall (or edge) of the conductive pad 130 and the portion of the through via 450A extended into the conductive pad 130 is greater than about 10 Å. On the other hand, as shown in FIG. 13, the through via 450B may further extend into the conductive pad 230 and stop at a position inside the conductive pad 230. For example, a portion of the through via 450B extended into the conductive pad 230 has a thickness D4, where the thickness D4 is less than or substantially equal to about 10 Å and is greater than or substantially equal to 0 Å. In other words, a thickness H230 of the conductive pad 230 is greater than the thickness D4, for example. For example, a minimum distance D5 between a sidewall (or edge) of the conductive pad 230 and the portion of the through via 450B extended into the conductive pad 230 is greater than about 10 Å. In some embodiments, a height difference D1 between the conductive pad 130 (e.g., the surface S130) and the conductive pad 230 (e.g., the surface S230) is greater than or substantially equal to 0 Å and is less than the thickness H130 of the conductive pad 130 and the thickness H230 of the conductive pad 230. For example, the height difference D1 may be 0 Å. Alternatively, the height difference D1 may be non-zero. In some embodiments, a height difference D2 between a bottom of the through via 450A and a bottom of the through via 450B is greater than or substantially equal to 0 Å and is less than the thickness H130 of the conductive pad 130 and the thickness H230 of the conductive pad 230. For example, the height difference D2 may be 0 Å. Alternatively, the height difference D2 may be non-zero.

For example, the metal barrier 250, which is considered as a part of the semiconductor die 200, is formed over the conductive pads 230 and embedded into the dielectric layer 240, where the through vias 450B penetrate through the dielectric layer 240 and the metal barrier 250 to be in (physical) contact with the conductive pads 230. In some embodiments, the metal barrier 250 may be made of TiN or TaN. For a non-limiting example, as shown in FIG. 8 and FIG. 14, only one through via 450A, one conductive pad 130, one through via 450B, one conductive pad 230, and a metal barrier 250 are emphasized, and the rest of features are omitted for simplicity. As shown in FIG. 14, the through via 450A may further extend into the conductive pad 130 and stop at a position inside the conductive pad 130. For example, a portion of the through via 450A extended into the conductive pad 130 has a thickness D3, where the thickness D3 is less than or substantially equal to about 10 Å and is greater than or substantially equal to 0 Å. In other words, a thickness H130 of the conductive pad 130 is greater than the thickness D3, for example. For example, a minimum distance D5 between a sidewall (or edge) of the conductive pad 130 and the portion of the through via 450A extended into the conductive pad 130 is greater than about 10 Å. On the other hand, as shown in FIG. 14, the through via 450B may penetrate through the metal barrier 250 and further extend into the conductive pad 230 and stop at a position inside the conductive pad 230. For example, a portion of the through via 450B extended into the conductive pad 230 has a thickness D4, where the thickness D4 is less than or substantially equal to about 10 Å and is greater than or substantially equal to 0 Å. In other words, a thickness H230 of the conductive pad 230 is greater than the thickness D4, for example. For example, a minimum distance D5 between a sidewall (or edge) of the conductive pad 230 and the portion of the through via 450B extended into the conductive pad 230 is greater than about 10 Å. In some embodiments, a height difference D1 between the conductive pad 130 (e.g., the surface S130) and the conductive pad 230 (e.g., the surface S230) is greater than or substantially equal to 0 Å and is less than the thickness H130 of the conductive pad 130 and the thickness H230 of the conductive pad 230. For example, the height difference D1 may be 0 Å. Alternatively, the height difference D1 may be non-zero. In some embodiments, a height difference D2 between a bottom of the through via 450A and a bottom of the through via 450B is greater than or substantially equal to 0 Å and is less than the thickness H130 of the conductive pad 130 and the thickness H230 of the conductive pad 230. For example, the height difference D2 may be 0 Å. Alternatively, the height difference D2 may be non-zero.

For example, the metal barrier 150, which is considered as a part of the semiconductor die 100, is formed over the conductive pads 130 and embedded into the dielectric layer 140, where the through vias 450A penetrate through the dielectric layer 140 and the metal barrier 150 to be in (physical) contact with the conductive pads 130, and the metal barrier 250, which is considered as a part of the semiconductor die 200, is formed over the conductive pads 230 and embedded into the dielectric layer 240, where the through vias 450B penetrate through the dielectric layer 240 and the metal barrier 250 to be in (physical) contact with the conductive pads 230. In some embodiments, the metal barriers 150, 250 individually may be made of TiN or TaN. For a non-limiting example, as shown in FIG. 8 and FIG. 15, only one through via 450A, one conductive pad 130, one through via 450B, one conductive pad 230, a metal barrier 150, and a metal barrier 250 are emphasized, and the rest of features are omitted for simplicity. As shown in FIG. 15, the through via 450A may penetrate through the metal barrier 150 and further extend into the conductive pad 130 and stop at a position inside the conductive pad 130. For example, a portion of the through via 450A extended into the conductive pad 130 has a thickness D3, where the thickness D3 is less than or substantially equal to about 10 Å and is greater than or substantially equal to 0 Å. In other words, a thickness H130 of the conductive pad 130 is greater than the thickness D3, for example. For example, a minimum distance D5 between a sidewall (or edge) of the conductive pad 130 and the portion of the through via 450A extended into the conductive pad 130 is greater than about 10 Å. On the other hand, as shown in FIG. 15, the through via 450B may penetrate through the metal barrier 250 and further extend into the conductive pad 230 and stop at a position inside the conductive pad 230. For example, a portion of the through via 450B extended into the conductive pad 230 has a thickness D4, where the thickness D4 is less than or substantially equal to about 10 Å and is greater than or substantially equal to 0 Å. In other words, a thickness H230 of the conductive pad 230 is greater than the thickness D4, for example. For example, a minimum distance D5 between a sidewall (or edge) of the conductive pad 230 and the portion of the through via 450B extended into the conductive pad 230 is greater than about 10 Å. In some embodiments, a height difference D1 between the conductive pad 130 (e.g., the surface S130) and the conductive pad 230 (e.g., the surface S230) is greater than or substantially equal to 0 Å and is less than the thickness H130 of the conductive pad 130 and the thickness H230 of the conductive pad 230. For example, the height difference D1 may be 0 Å. Alternatively, the height difference D1 may be non-zero. In some embodiments, a height difference D2 between a bottom of the through via 450A and a bottom of the through via 450B is greater than or substantially equal to 0 Å and is less than the thickness H130 of the conductive pad 130 and the thickness H230 of the conductive pad 230. For example, the height difference D2 may be 0 Å. Alternatively, the height difference D2 may be non-zero.

The above embodiments, the thickness D3 and the thickness D4 may be non-zero. However, the disclosure is not limited thereto. In some embodiments, the through vias 450A may penetrate the metal barrier 150 (if any) and stop at the surface S130t of the conductive pad 130, where the thickness D3 is 0 Å. In some embodiments, the through vias 450B may penetrate the metal barrier 250 (if any) and stop at the surface S230t of the conductive pad 230, where the thickness D4 is 0 Å. The disclosure is not limited thereto.

As shown in FIG. 8, in some embodiments, the through vias 450A are further electrically coupled to the interconnect structure 320 of the semiconductor die 300 by directly connecting the patterned conductive layer 324 so to electrically connect the semiconductor die 300 and the semiconductor die 100. However, the disclosure is not limited thereto. Alternatively or in addition to, the through vias 450A are electrically coupled to the interconnect structure 320 of the semiconductor die 300 by a later-formed component (e.g., a routing structure overlying thereto) so to electrically connect the semiconductor die 300 and the semiconductor die 100. That is, the through vias 450A may further be (or be a part of) input/output (I/O) structure of the semiconductor dies 100. As shown in FIG. 8, in some embodiments, the through vias 450B are further electrically coupled to the interconnect structure 320 of the semiconductor die 300 by directly connecting the patterned conductive layer 324 so to electrically connect the semiconductor die 300 and the semiconductor die 200. However, the disclosure is not limited thereto. Alternatively or in addition to, the through vias 450B are electrically coupled to the interconnect structure 320 of the semiconductor die 300 by a later-formed component (e.g., a routing structure overlying thereto) so to electrically connect the semiconductor die 300 and the semiconductor die 200. On the other hand, the through vias 450B may further be (or be a part of) input/output (I/O) structure of the semiconductor dies 200. Up to here, a second tier of the semiconductor device 1000 (FIG. 11) is manufactured, where the second tier includes the semiconductor die 300, the through vias 450, the insulating encapsulant 440 and the bonding layer 430, and the through vias 450 (including 450A and 450B) share a common pitch P1 a common critical dimension (CD) W1.

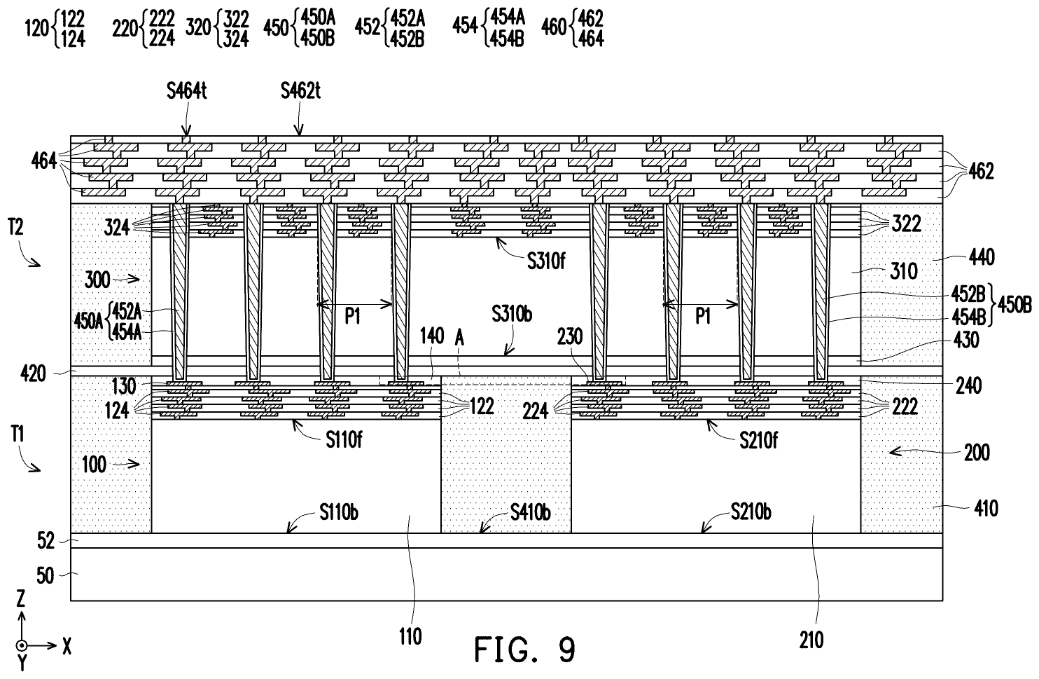

Referring to FIG. 9, in some embodiments, a routing structure 460 is formed on the second tier of the semiconductor device 1000 to be electrically coupled to the semiconductor die 300 and the through vias 450. The routing structure 460 may include one or more inter-dielectric layers 462 and one or more patterned conductive layers 464 stacked alternately. For examples, the inter-dielectric layers 462 are silicon oxide layers, silicon nitride layers, silicon oxy-nitride layers, or dielectric layers formed by other suitable dielectric materials, and are formed by deposition or the like. For examples, the patterned conductive layers 464 are patterned copper layers or other suitable patterned metal layers, and are formed by electroplating or deposition. However, the disclosure is not limited thereto. Alternatively, the patterned conductive layers 464 may be formed by a single or dual-damascene method. The number of the inter-dielectric layers 462 and the number of the patterned conductive layers 464 may be less than or more than what is depicted in FIG. 9, and may be designated and selected based on the demand and/or design layout; the disclosure is not specifically limited thereto. In some embodiments, the patterned conductive layers 464 are sandwiched between the inter-dielectric layers 462, where a surface S464t of an outermost layer of the patterned conductive layers 464 is exposed by a surface S462t of an outermost layer of the inter-dielectric layers 462 to connect to later formed component(s) for electrical connection, and a surface of an innermost layer of the patterned conductive layers 464 is exposed by an innermost layer of the inter-dielectric layers 462 and electrically connected to the interconnect structure 320 of the semiconductor die 300 and the through vias 450 (e.g., 450A and 450B). With the through vias 450, the semiconductor dies 100 and 200 may be electrically coupled to the routing structure 460. In other words, the routing structure 460 may be referred to as an interconnect structure of the semiconductor device 1000, which is able to provide the routing functions to the components (e.g., the semiconductor dies 100, 200 and 300) formed in the semiconductor device 1000. As shown in FIG. 9, for example, the surface S464t of the outermost layer of the patterned conductive layers 464 is substantially level with the surface S462t of an outermost layer of the inter-dielectric layers 462. That is, the surface S464t of the outermost layer of the patterned conductive layers 464 may be substantially coplanar to the surface S462t of an outermost layer of the inter-dielectric layers 462.

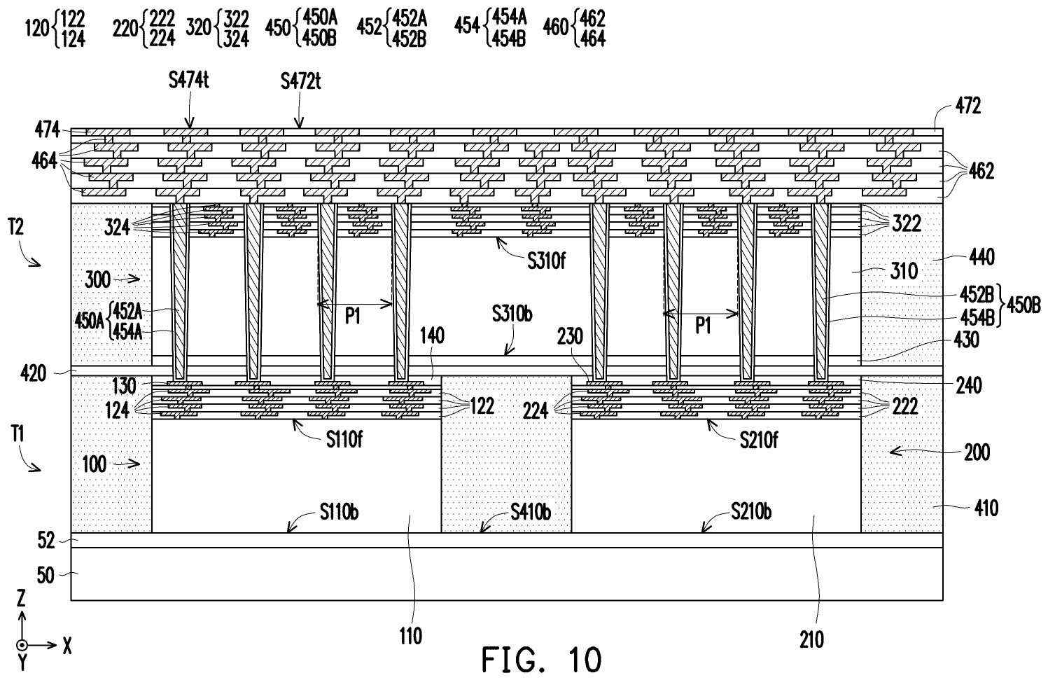

Referring to FIG. 10, in some embodiments, a dielectric layer 472 and a plurality of conductive pads 474 are formed on the routing structure 460, and sidewalls of the conductive pads 474 are wrapped around by (e.g., in physical contact with) the dielectric layer 472. As shown in FIG. 10, surfaces S474t of the conductive pads 474 are accessibly revealed by a surface S472t of the dielectric layer 472. In some embodiments, the conductive pads 474 are laterally covered by the dielectric layer 472. The conductive pads 474 may together be referred to as top metals of the semiconductor device 1000. Through the routing structure 460, the conductive pads 474 are electrically connected to the semiconductor dies 100, 200 and 300 formed in the semiconductor device 1000. For simplification, only nine conductive pads 474 are presented in FIG. 10 for illustrative purposes, however it should be noted that more than nine conductive pads 474 may be formed; the disclosure is not limited thereto.

In some embodiments, the conductive pads 474 are formed by photolithography, plating, photoresist stripping processes or any other suitable method. The plating process may include an electroplating plating, an electroless plating, or the like. For example, the conductive pads 474 is formed by, but not limited to, conformally forming a seed layer (not shown) over the routing structure 460, forming a mask pattern (not shown) covering the seed layer over the routing structure 460 with opening holes (not shown) corresponding to the surface of the outermost layer of the patterned conductive layers 464 exposed by the outermost layer of the inter-dielectric layers 462, forming a metallic material over the seed layer exposed by the opening holes and to fill the opening holes formed in the mask pattern by electroplating or deposition, removing the mask pattern, and removing the seed layer exposed by the metallic material so to form the conductive pads 474. The seed layer may be referred to as a metal or metallic layer, which can be a single layer or a composite layer including a plurality of sub-layers formed of different materials. The material of the seed layer may include titanium, copper, molybdenum, tungsten, titanium nitride, titanium tungsten, combinations thereof, or the like, which may be formed using, for example, sputtering, PVD, or the like. For example, the seed layer may be or include a titanium layer and a copper layer over the titanium layer. The seed layer may be removed by an etching process, such a dry etching process, a wet etching process, or the combination thereof. The mask pattern may be removed by acceptable ashing process and/or photoresist stripping process, such as using an oxygen plasma or the like. In one embodiment, the material of the conductive pads 474 includes a metal material such as copper, copper alloys, aluminum, aluminum alloys, molybdenum, tungsten, titanium, tantalum, or the like. For example, the conductive pads 474 may be made of aluminum. In some embodiments, in the top (plane) view on the X-Y plane, the conductive pads 474 may independently be in a circle-shape, an ellipse-shape, a triangle-shape, a rectangle-shape, a polygonal shape, a pre-determined shape (e.g., a main body with branches) or the like. The shape of the conductive pads 474 is not limited in the disclosure. The shape and number of the conductive pads 474 may be designated and selected based on the demand and design layout.

In some embodiments, as shown in FIG. 10, the dielectric layer 472 is formed on the routing structure 460 to laterally cover the conductive pads 474, where the routing structure 460 exposed by the conductive pads 474 is covered by and in contact with the dielectric layer 472. As shown in FIG. 10, the dielectric layer 472 has a substantially planar surface (e.g., a surface S472t) accessibly revealing surface S474 of the conductive pads 474, for example. In some embodiments, the dielectric layer 472 includes a PI layer, a PBO layer, a silicon dioxide based (non-organic) layer or other suitable polymer (or organic) layer, and is formed by deposition or the like. For example, the dielectric layer 472 may be made of silicon oxide or silicon oxynitride. The disclosure is not limited thereto. The dielectric layer 472 may be referred to as a passivation layer for providing protection to the conductive pads 474. In some embodiments, the surface S472t of the dielectric layer 472 is substantially level with the surfaces S474t of the conductive pads 474. That is, the surface S472t of the dielectric layer 472 may be substantially coplanar to the surfaces S474t of the conductive pads 474.

Referring to FIG. 11, in some embodiments, a plurality of conductive terminals 480 are formed on the conductive pads 474 and over the routing structure 460. The conductive terminals 480 are disposed on (e.g., in physical contact with) and electrically coupled to the conductive pads 474, for example. As shown in FIG. 11, the conductive terminals 480 may be electrically coupled to the routing structure 460 through the conductive pads 474. In some embodiments, some of the conductive terminals 480 are electrically coupled to the semiconductor die 300 through the conductive pads 474 and the routing structure 460. In some embodiments, some of the conductive terminals 480 are electrically coupled to the through vias 450 through the conductive pads 474 and the routing structure 460. In some embodiments, some of the conductive terminals 480 are electrically coupled to the semiconductor die 100 through the conductive pads 474, the routing structure 460 and the through vias 450. In some embodiments, some of the conductive terminals 480 are electrically coupled to the semiconductor die 200 through the conductive pads 474, the routing structure 460 and the through vias 450. Each of the conductive terminals 480, for example, includes micro-bumps, metal pillars, controlled collapse chip connection (C4) bumps (for example, which may have, but not limited to, a size of about 80μm), a ball grid array (BGA) bumps (for example, which may have, but not limited to, a size of about 400μm), electroless nickel-immersion gold technique (ENIG) formed bumps, electroless nickel-electroless palladium-immersion gold technique (ENEPIG) formed bumps, or the like. The disclosure is not limited thereto. The shape and number of the conductive terminals 480 are not limited in the disclosure. The conductive terminals 480 may be referred to as conductor or connector of the semiconductor device 1000 (FIG. 11).

After forming the conductive terminals 480, a dicing (singulation) process is performed to cut through the dielectric layer 472, the routing structure 460, the insulating encapsulant 440, the bonding layer 420 and the insulating encapsulant 410 to form a plurality of semiconductor devices 1000. Up to here, the semiconductor device 1000 is manufactured. In FIG. 11, only one semiconductor device 1000 is shown for illustrative purposes and simplicity. The semiconductor device 1000 each may include the carrier 50, the dielectric layer 52 disposed over the carrier 50, the first tier (including the semiconductor die 100, the semiconductor 200, the insulting encapsulant 410 and the bonding layer 420) disposed over the dielectric layer 52, the second tier (including the semiconductor die 300, the bonding layer 430, the insulating encapsulant 440 and the through vias 450) disposed on and electrically coupled to the first tier, the routing structure 460 disposed on and electrically coupled to the second tier, the conductive pads 472 disposed on and electrically coupled to the routing structure 460, the dielectric layer 474 disposed on the routing structure 460 and laterally covering the conductive pads 474, and the conductive terminals 480 disposed on and electrically coupled to the conductive pads 474. For example, in the semiconductor device 1000, a sidewall SW50 of the carrier 50, a sidewall SW52 of the dielectric layer 52, a sidewall SW410 of the insulating encapsulant 410, a sidewall SW420 of the bonding layer 420, a sidewall SW440 of the insulating encapsulant 440, a sidewall SW460 of the routing structure 460, and a sidewall SW472 of the dielectric layer 472 are aligned to each other. That is, the sidewall SW50 of the carrier 50, the sidewall SW52 of the dielectric layer 52, the sidewall SW410 of the insulating encapsulant 410, the sidewall SW420 of the bonding layer 420, the sidewall SW440 of the insulating encapsulant 440, the sidewall SW460 of the routing structure 460, and the sidewall SW472 of the dielectric layer 472 are together constitute a sidewall of the semiconductor device 1000. In one embodiment, the dicing (singulation) process is a wafer dicing process including mechanical blade sawing or laser cutting. The disclosure is not limited thereto.

In some embodiments, prior to the dicing (singulation) process, a debonding process is performed to remove the carrier 50 and dielectric layer 52. In one embodiment, the debonding process is a laser debonding process.

In the above embodiments, the through vias 450A and the through vias 450B share the common pitch P1 and the common CD W1. However, the disclosure is not limited thereto.

In some embodiments, a semiconductor device 2000 of FIG. 16 is similar to the semiconductor device 1000 of FIG. 11, and the difference is that, the through vias 450A have a CD W1 and a pitch P1, and the through vias 450B have a CD W1 and a pitch P2, where the pitch P1 is different from the pitch P2. For example, as shown in FIG. 16, the pitch P1 is less than the pitch P2. However, the disclosure is not limited thereto; alternatively, the pitch P1 may be greater than the pitch P2.

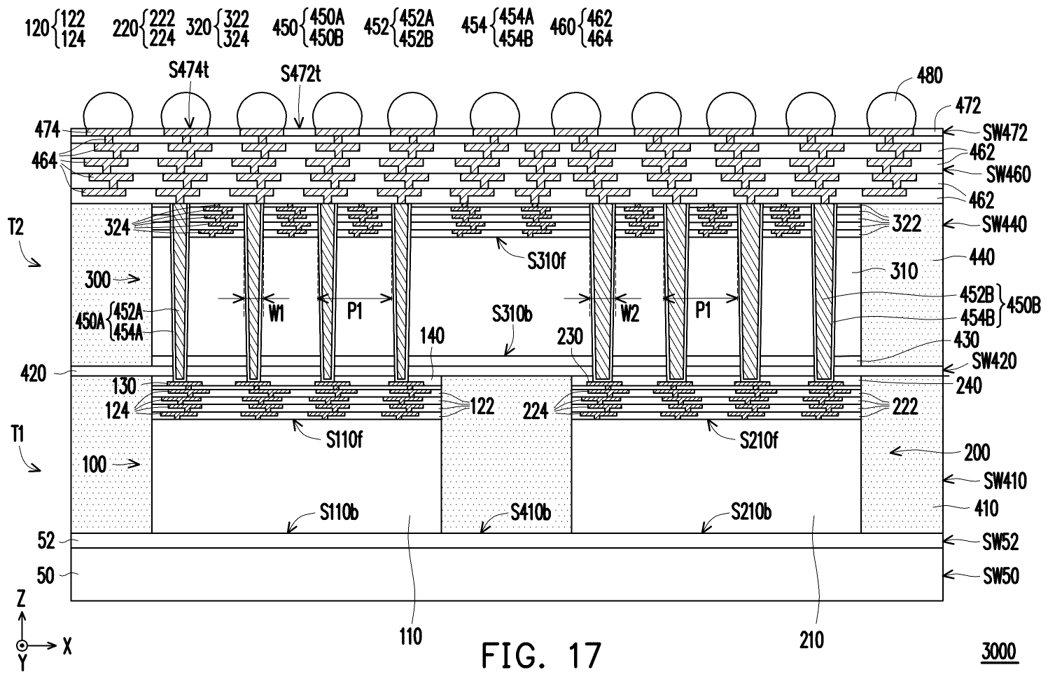

In some embodiments, a semiconductor device 3000 of FIG. 17 is similar to the semiconductor device 1000 of FIG. 11, and the difference is that, the through vias 450A have a CD W1 and a pitch P1, and the through vias 450B have a CD W2 and a pitch P1, where the CD W1 is different from the CD W2. For example, as shown in FIG. 17, the CD W1 is less than the CD W2. However, the disclosure is not limited thereto; alternatively, the CD W1 may be greater than the CD W2.

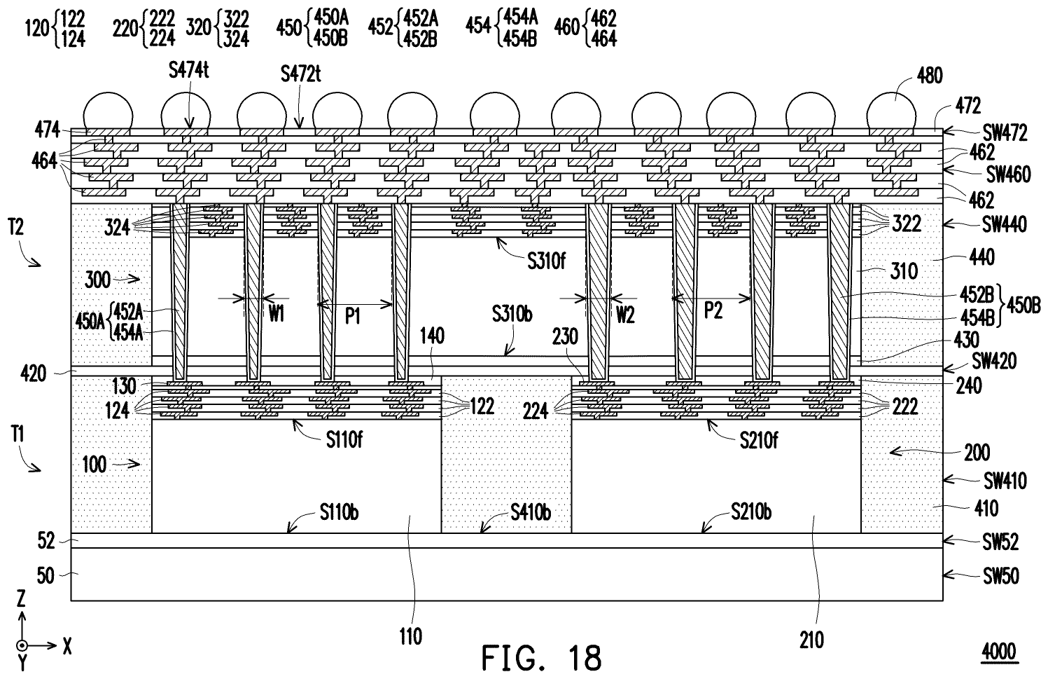

In some embodiments, a semiconductor device 4000 of FIG. 18 is similar to the semiconductor device 1000 of FIG. 11, and the difference is that, the through vias 450A have a CD W1 and a pitch P1, and the through vias 450B have a CD W2 and a pitch P2, where the pitch P1 is different from the pitch P2, and the CD W1 is different from the CD W2. For example, as shown in FIG. 18, the pitch P1 is less than the pitch P2, and the CD W1 is less than the CD W2. However, the disclosure is not limited thereto; alternatively, the pitch P1 may be greater than the pitch P2, and the CD W1 may be greater than the CD W2. Or, the pitch P1 may be greater than the pitch P2, and the CD W1 may be less than the CD W2. Or, the pitch P1 may be less than the pitch P2, and the CD W1 may be greater than the CD W2.

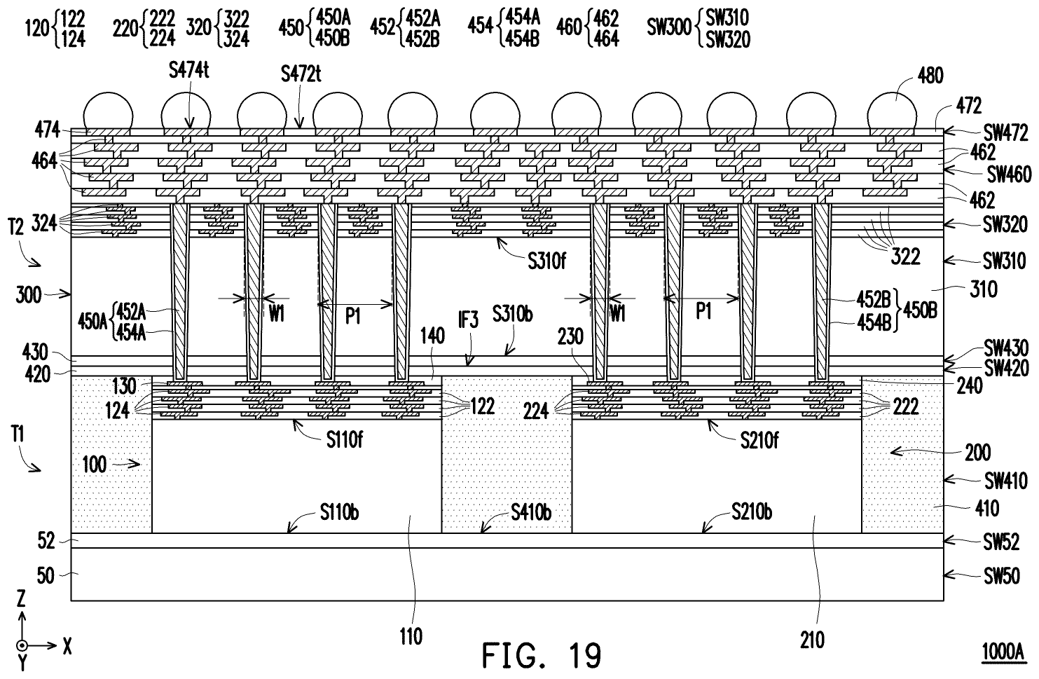

In the above embodiments, the semiconductor die 300 is bonded to the first tier of the semiconductor device (e.g., 1000. 2000, 3000, and 400) by CoW bonding. However, the disclosure is not limited thereto. In some embodiments, a semiconductor device 1000A of FIG. 19 is similar to the semiconductor device 1000 of FIG. 11, and the difference is that, for semiconductor device 1000A, in the process of FIG. 6, the semiconductor die 300 (in wafer form) is bonded to the first tier by a wafer-on-wafer (WoW) bonding with the bonding interface IF3 between the bonding layer 420 and the bonding layer 430, and thus the insulating encapsulant 440 is omitted therefrom. The details of the bonding interface IF3 have been discussed in FIG. 6, and thus are not repeated. That is, the semiconductor device 1000A includes the carrier 50, the dielectric layer 52 disposed over the carrier 50, the first tier (including the semiconductor die 100, the semiconductor 200, the insulting encapsulant 410 and the bonding layer 420) disposed over the dielectric layer 52, the second tier (including the semiconductor die 300, the bonding layer 430 and the through vias 450) disposed on and electrically coupled to the first tier, the routing structure 460 disposed on and electrically coupled to the second tier, the conductive pads 472 disposed on and electrically coupled to the routing structure 460, the dielectric layer 474 disposed on the routing structure 460 and laterally covering the conductive pads 474, and the conductive terminals 480 disposed on and electrically coupled to the conductive pads 474. For example, in the semiconductor device 1000A, a sidewall SW50 of the carrier 50, a sidewall SW52 of the dielectric layer 52, a sidewall SW410 of the insulating encapsulant 410, a sidewall SW420 of the bonding layer 420, a sidewall SW430 of the bonding layer 430, a sidewall SW300 (including a sidewall SW310 of the semiconductor substrate 310 and a sidewall SW320 of the interconnect structure 320) of the semiconductor die 300, a sidewall SW460 of the routing structure 460, and a sidewall SW472 of the dielectric layer 472 are aligned to each other. That is, the sidewall SW50 of the carrier 50, the sidewall SW52 of the dielectric layer 52, the sidewall SW410 of the insulating encapsulant 410, the sidewall SW420 of the bonding layer 420, the sidewall SW430 of the bonding layer 430, the sidewall SW300 of the semiconductor die 300, the sidewall SW460 of the routing structure 460, and the sidewall SW472 of the dielectric layer 472 are together constitute a sidewall of the semiconductor device 1000A. The configurations described in FIG. 12, FIG. 13, FIG. 14 and/or FIG. 15 may also applied to the semiconductor device 1000A. The disclosure is not limited thereto, alternatively or in addition to, some modifications of the semiconductor devices 2000, 3000, and/or 4000 may be achieved with WoW bonding process described in FIG. 19 and/or configurations described in FIG. 12, FIG. 13, FIG. 14 and/or FIG. 15.

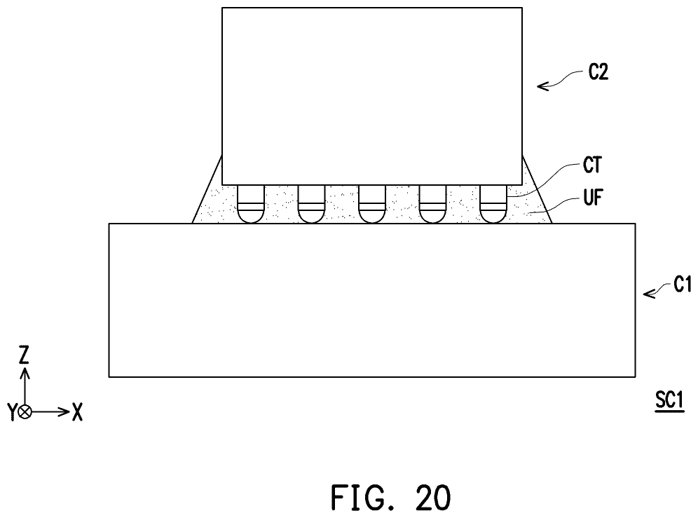

FIG. 20 is a schematic cross-sectional view showing an application of a semiconductor device (e.g., the semiconductor devices 1000, 2000, 3000, 4000, 1000A, and/or modifications thereof) in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 20, in some embodiments, a component assembly SC including a first component C1 and a second component C2 disposed over the first component C1 is provided. The first component C1 may be or may include a circuit structure, such as a mother board, a package substrate, a printed circuit board (PCB), a printed wiring board, an interposer, a redistribution circuit layer or structure, and/or other carrier that is capable of carrying integrated circuits. In some embodiments, the second component C2 mounted on the first component C1 is similar to one of the semiconductor devices 1000, 2000, 3000, 4000, 1000A, and/or modifications thereof. For example, one or more second components C2 (e.g., 1000, 2000, 3000, 4000, 1000A, and/or modifications thereof) may be electrically coupled to the first component C1 through a plurality of terminals CT. The terminals CT may be the conductive terminals 480. In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill UF may be formed by underfill dispensing, a capillary flow process, or any other suitable method. Owing to the underfill UF, a bonding strength between the first component C1 and the second component C2 is enhanced.

In accordance with some embodiments, a semiconductor device includes a die stack. The die stack includes a first tier including a first die and a second tier disposed over the first tier and including a second die and a plurality of through vias, where the plurality of through vias penetrate through the second die and further extend into a part of the first tier to be electrically coupled to the first die.

In accordance with some embodiments, a semiconductor device includes a first semiconductor die, a second semiconductor die, a third semiconductor die, a first through via, and a second through via. The first semiconductor die includes a first bonding pad. The second semiconductor die is arranged next to the first semiconductor die in a first direction and includes a second bonding pad. The third semiconductor die is disposed over the first semiconductor die and the second semiconductor die in a second direction. The first through via penetrates the third semiconductor die and further extends into the first bonding pad. The second through via penetrates the third semiconductor die and further extending into the second bonding pad.

In accordance with some embodiments, a method of manufacturing a semiconductor device includes the following steps: providing a first semiconductor die and a second semiconductor die arranged next to the first semiconductor die; encapsulating the first semiconductor die and the second semiconductor die in a first insulating encapsulant; forming a first bonding layer over the first insulating encapsulant and extending onto the first semiconductor die and the second semiconductor die; providing a third semiconductor die with a second bonding layer disposed thereon; bonding the third semiconductor die to the first semiconductor die and the second semiconductor die by connecting the first bonding layer and the second bonding layer; forming a first through via penetrating through the third semiconductor die to be in contact with a first bonding pad of the first semiconductor die so to electrically couple the first through via and the first semiconductor die; forming a second through via penetrating through the third semiconductor die to be in contact with a second bonding pad of the second semiconductor die so to electrically couple the second through via and the second semiconductor die; disposing a routing structure over the third semiconductor die, the first through via and the second through via for electrically coupling therebetween; and forming a plurality of conductive terminals over the routing structure.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor device, comprising:
a die stack, comprising:
a first tier, comprising a first die; and
a second tier, disposed over the first tier and comprising a second die and a plurality of through vias, wherein the plurality of through vias penetrate through the second die and further extend into a part of the first tier to be electrically coupled to the first die.

2. The semiconductor device of claim 1, wherein the first die comprises:
a semiconductor substrate;
a interconnect structure, disposed over the semiconductor substrate;
a plurality of conductive pads, disposed over and electrically coupled to the interconnect structure; and
a dielectric layer, covering the plurality of conductive pads and the interconnect structure exposed by the plurality of conductive pads,
wherein the plurality of through vias penetrate through the second die and the dielectric layer and are in contact with the plurality of conductive pads.

3. The semiconductor device of claim 2, wherein the plurality of through vias further extend into a part of the plurality of conductive pads, respectively.

4. The semiconductor device of claim 2, wherein the plurality of through vias each comprise a portion having a sidewall laterally covered by the dielectric layer and a bottom covered by a respective one of the plurality of conductive pads.

5. The semiconductor device of claim 2, wherein the plurality of through vias each comprise a portion having a sidewall laterally covered by the dielectric layer and a respective one of the plurality of conductive pads and a bottom covered by the respective one of the plurality of conductive pads.

6. The semiconductor device of claim 1,
wherein the first tier further comprises:
a first insulating encapsulant, laterally encapsulating the first die; and
a first bonding layer, disposed over the first insulating encapsulant and the first die, wherein the plurality of through vias further penetrate through the first bonding layer, and
wherein the second tier further comprises:
a second insulating encapsulant, laterally encapsulating the second die; and
a second bonding layer, disposed between the second die and the first bonding layer, wherein the plurality of through vias further penetrate through the second bonding layer.

7. The semiconductor device of claim 6, wherein the second insulating encapsulant further laterally encapsulates the second bonding layer.

8. The semiconductor device of claim 6, wherein there is a dielectric-to-dielectric bonding interface between the first bonding layer and the second bonding layer.

9. A semiconductor device, comprising:
a first semiconductor die, comprising a first bonding pad;
a second semiconductor die, arranged next to the first semiconductor die in a first direction and comprising a second bonding pad;
a third semiconductor die, disposed over the first semiconductor die and the second semiconductor die in a second direction;
a first through via, penetrating the third semiconductor die and further extending into the first bonding pad; and
a second through via, penetrating the third semiconductor die and further extending into the second bonding pad.

10. The semiconductor device of claim 9, wherein a material of the first bonding pad is different from a material of the second bonding pad.

11. The semiconductor device of claim 9, wherein in the second direction, a non-zero distance is between a bottom surface of the first through via disposed in the first bonding pad and a bottom surface of the second through via disposed in the second bonding pad.

12. The semiconductor device of claim 9,
wherein the first bonding pad has a first top surface and a first bottom surface opposing to the first top surface in the second direction, and the first top surface is closer to the third semiconductor die than the first bottom surface,
wherein the second bonding pad has a second top surface and a second bottom surface opposing to the second top surface in the second direction, and the second top surface is closer to the third semiconductor die than the second bottom surface,
wherein in the second direction, a non-zero distance is between the first top surface and the second top surface.

13. The semiconductor device of claim 9, wherein in the second direction, a portion of the first through via disposed inside the first bonding pad has a thickness being less than or substantially equal to about 10 Å.

14. The semiconductor device of claim 9, wherein in the second direction, a portion of the second through via disposed inside the second bonding pad has a thickness being less than or substantially equal to about 10 Å.

15. The semiconductor device of claim 9, wherein in the first direction,
a first minimum distance between an edge of a portion of the first through via disposed inside the first bonding pad and an edge of the first bonding pad is greater than about 10 Å, and
a second minimum distance between an edge of a portion of the second through via disposed inside the second bonding pad and an edge of the second bonding pad is greater than about 10 Å.

16. A method of manufacturing a semiconductor device, comprising:
providing a first semiconductor die and a second semiconductor die arranged next to the first semiconductor die;
encapsulating the first semiconductor die and the second semiconductor die in a first insulating encapsulant;
forming a first bonding layer over the first insulating encapsulant and extending onto the first semiconductor die and the second semiconductor die;
providing a third semiconductor die with a second bonding layer disposed thereon;
bonding the third semiconductor die to the first semiconductor die and the second semiconductor die by connecting the first bonding layer and the second bonding layer;
forming a first through via penetrating through the third semiconductor die to be in contact with a first bonding pad of the first semiconductor die so to electrically couple the first through via and the first semiconductor die;
forming a second through via penetrating through the third semiconductor die to be in contact with a second bonding pad of the second semiconductor die so to electrically couple the second through via and the second semiconductor die;
disposing a routing structure over the third semiconductor die, the first through via and the second through via for electrically coupling therebetween; and
forming a plurality of conductive terminals over the routing structure.

17. The method of claim 16, wherein bonding the third semiconductor die to the first semiconductor die and the second semiconductor by a dielectric-to-dielectric bonding.

18. The method of claim 16, wherein the first through via and the second through via are formed in different steps.

19. The method of claim 16, wherein forming the first through via penetrating through the third semiconductor die to be in contact with the first bonding pad of the first semiconductor die comprises forming the first through via penetrating through the third semiconductor die and further extending into a portion of the first bonding pad to be in contact with the first bonding pad of the first semiconductor die, and
wherein forming the second through via penetrating through the third semiconductor die to be in contact with the second bonding pad of the second semiconductor die comprises forming the second through via penetrating through the third semiconductor die and further extending into a portion of the second bonding pad to be in contact with the second bonding pad of the second semiconductor die.

20. The method of claim 16, further comprising:
encapsulating the second bonding layer and the third semiconductor die in a second insulating encapsulant.
